(19) United States
(12) Patent Application Publication
(10) Pub. No.: US 2026/0291371 A1
(43) Pub. Date: Sep. 24, 2026

(54) ELECTRONIC CIRCUITRY, POWER CONVERTER, AND DRIVING METHOD

(71) Applicant: Kabushiki Kaisha Toshiba, Kawasaki-shi (JP)

(72) Inventors: Shusuke KAWAI, Fujisawa Kanagawa (JP); Hiroaki ISHIHARA, Yokohama Kanagawa (JP); Takeshi UENO, Kawasaki Kanagawa (JP); Koutaro MIYAZAKI, Taito Tokyo (JP); Kohei HORII, Kawasaki Kanagawa (JP); Yuto BUSHIMATA, Kawasaki Kanagawa (JP)

(21) Appl. No.: 19/535,380

(22) Filed: Feb. 10, 2026

(30) Foreign Application Priority Data
Mar. 19, 2025 (JP) 2025-045982

(51) Int. Cl. H02M 1/084; H02M 1/00; H02M 7/5387; H03K 17/16; H03K 17/284; H03K 17/30

(52) U.S. Cl. CPC H02M 1/084; H02M 1/0009; H02M 1/0058; H02M 7/53871; H03K 17/163; H03K 17/284; H03K 17/302; H03K 2217/0063; H03K 2217/0072

(57) ABSTRACT

According to one embodiment, an electronic circuitry includes a detection circuit detecting a physical quantity corresponding to a temporal change of an output current or voltage of a switching element controlled to turn on or off. A controller switches a current value commanding a magnitude of a drive current supplied to the switching element at a transition timing corresponding to the physical quantity. A current supply circuit supplies the drive current based on the current values before and after switching. A calculation circuit calculates a slew rate of the output voltage or current in a period before or after the switching. The controller determines the current value for a subsequent turn-on or turn-off according to the calculated slew rate.

### CROSS REFERENCE TO RELATED APPLICATIONS

This application is based upon and claims the benefit of priority from the prior Japanese Patent Application No. 2025-045982, filed on Mar. 19, 2025, the entire contents of which are incorporated herein by reference.

### FIELD

Embodiments described herein relate to an electronic circuitry, a power converter, and a driving method.

### BACKGROUND

A switching element used in a power circuit, an inverter, or the like exhibits a smaller power loss as a transition time during turn-on or turn-off is shorter. However, electromagnetic noise (electro-magnetic interference (EMI)) is generated during turn-on or turn-off of the switching element, and the magnitude of EMI is larger as the transition time is shorter. In other words, the power loss and EMI are in a trade-off relationship.

In order to adjust such trade-off, it is conceivable to control drive current supplied to the switching element such that the slew rate of output voltage or output current during turn-on or turn-off of the switching element is adjusted to a desired value. However, for example, in a case where the switching element is a MOSFET, it is known that different physical mechanisms are determinative of a temporal change of the output voltage between the first half and the second half of a turn-on period. Specifically, in the first half of the turn-on period, the output voltage decreases mainly due to the effect of parasitic inductance, whereas in the second half of the turn-on period, the output voltage decreases mainly due to the effect of drain-gate capacitance.

### BRIEF DESCRIPTION OF THE DRAWINGS

FIG. 1 is a diagram illustrating the configuration of a half-bridge inverter according to Embodiment 1;

FIG. 2 is a diagram illustrating an operation of a switching element during turn-on;

FIG. 3 is a diagram illustrating an operation of the switching element during turn-off;

FIG. 4 is a diagram illustrating a detailed configuration of a drive circuit;

FIG. 5 is a diagram illustrating a detailed configuration of a turn-on current command circuit;

FIG. 6 is a diagram for description of an operation of the drive circuit during turn-on;

FIG. 7 is a diagram illustrating a detailed configuration of a turn-off current command circuit;

FIG. 8 is a diagram for description of an operation of the drive circuit during turn-off;

FIG. 9 is a diagram for description of an operation of the drive circuit according to Embodiment 2 during turn-on;

FIG. 10 is a diagram for description of an operation of the drive circuit according to Embodiment 2 during turn-off;

FIG. 11 is a diagram for description of an operation of the drive circuit according to Embodiment 3 during turn-on;

FIG. 12 is a diagram for description of an operation of the drive circuit according to Embodiment 3 during turn-off; and

FIG. 13 is a diagram illustrating the configuration of a three-phase inverter according to Embodiment 4.

### DETAILED DESCRIPTION

According to one embodiment, an electronic circuitry includes: a detection circuit configured to detect a physical quantity corresponding to a temporal change of an output current or an output voltage of a switching element whose drive is controlled in accordance with a control signal instructing turn-on or turn-off; a controller configured to switch a current value commanding a magnitude of a drive current to be supplied to the switching element at a transition timing corresponding to the detected physical quantity; a current supply circuit configured to supply the drive current to the switching element based on the current value before switching and the current value after switching; and a calculation circuit configured to calculate a slew rate of the output voltage or the output current of the switching element in a period before the switching or a period after the switching. The controller is configured to determine the current value before switching or the current value after switching to be used during next or subsequent turn-on or turn-off of the switching element in accordance with the calculated slew rate.

According to one embodiment, a power converter includes: a half-bridge circuit including two switching elements; and two drive circuits configured to drive the two switching elements, respectively, in accordance with control signals instructing turn-on or turn-off. Each of the two drive circuits includes: a detection circuit configured to detect a physical quantity corresponding to a temporal change of an output current or an output voltage of the switching element controlled by the drive circuit; a controller configured to switch a current value commanding a magnitude of a drive current to be supplied to the switching element at a transition timing corresponding to the detected physical quantity; a current supply circuit configured to supply the drive current to the switching element based on the current value before switching and the current value after switching; and a calculation circuit configured to calculate a slew rate of the output voltage or the output current of the switching element in a period before the switching or a period after the switching. The controller is configured to determine the current value before switching or the current value after switching to be used during next or subsequent turn-on or turn-off of the switching element in accordance with the calculated slew rate.

According to one embodiment, a driving method includes: detecting a physical quantity corresponding to a temporal change of an output current or an output voltage of a switching element whose drive is controlled in accordance with a control signal instructing turn-on or turn-off; switching a current value commanding a magnitude of a drive current to be supplied to the switching element at a transition timing corresponding to the detected physical quantity; supplying the drive current to the switching element based on the current value before switching and the current value after switching; calculating a slew rate of the output voltage or the output current of the switching element in a period before the switching or a period after the switching; and determining the current value before switching or the current value after switching to be used during next or subsequent turn-on or turn-off of the switching element in accordance with the calculated slew rate.

The present embodiment will be described below with reference to the accompanying drawings. In the drawings, identical or corresponding elements are denoted by the same reference sign, and detailed description thereof will not be repeated as appropriate.

### Embodiment 1

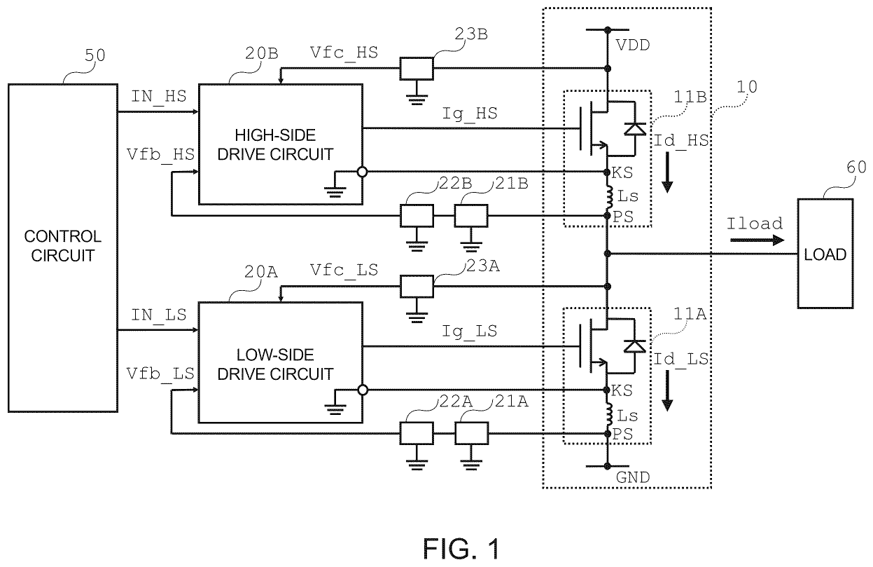

FIG. 1 is a diagram illustrating the configuration of a half-bridge inverter that is a power converter according to Embodiment 1. The half-bridge inverter includes a half-bridge circuit 10, a low-side drive circuit 20A, a high-side drive circuit 20B, and a control circuit 50. A load 60 is connected to an output of the half-bridge inverter.

The half-bridge circuit 10 includes a low-side switching element 11A and a high-side switching element 11B, which are controlled to be driven in accordance with control signals supplied from the control circuit 50. For example, the switching elements 11A and 11B may be N-channel metal oxide semiconductor field effect transistors (MOSFETS). In this case, the switching elements 11A and 11B may each include a Kelvin source terminal (KS) in addition to gate, drain, and power source (PS) terminals. Hereinafter, the switching elements 11A and 11B are described as including the Kelvin source terminal (KS), but the technical applicable range of the present embodiment is not limited to MOSFETs including the Kelvin source terminal (KS).

Alternatively, the switching elements 11A and 11B may be N-channel insulated gate bipolar transistors (IGBTs). In this case, the switching elements 11A and 11B may each include a Kelvin emitter terminal (KE) in addition to gate, collector, and power emitter (PE) terminals. However, the technical applicable range of the present embodiment is not limited to IGBTs including the Kelvin source terminal (KS).

The drain of the low-side switching element 11A is connected to the power source PS of the high-side switching element 11B. The Kelvin source KS of the switching element 11A is connected to a ground of the low-side drive circuit 20A. A parasitic inductance Ls (low-side parasitic inductance Ls) is included between the Kelvin source KS and the power source PS of the switching element 11A. The power source PS of the switching element 11A is connected to a ground GND of the half-bridge inverter.

The power source PS of the switching element 11A is connected to the low-side drive circuit 20A through an attenuator 21A and a DC bias circuit 22A. The attenuator 21A and the DC bias circuit 22A are connected to the same ground as the low-side drive circuit 20A. However, in a case where the voltage between the Kelvin source KS and the power source PS of the switching element 11A falls within an input range of the low-side drive circuit 20A, one or both of the attenuator 21A and the DC bias circuit 22A may be omitted. The drain of the switching element 11A is connected to the low-side drive circuit 20A through an attenuator 23A. The attenuator 23A is connected to the same ground as the low-side drive circuit 20A. However, in a case where a drain-source voltage of the switching element 11A falls within the input range of the low-side drive circuit 20A, the attenuator 23A may be omitted.

The drain of the high-side switching element 11B is connected to a power voltage VDD of the half-bridge inverter. The Kelvin source KS of the switching element 11B is connected to a ground of the high-side drive circuit 20B. A parasitic inductance Ls (high-side parasitic inductance Ls) is included between the Kelvin source KS and the power source PS of the switching element 11B.

The power source PS of the switching element 11B is connected to the high-side drive circuit 20B through an attenuator 21B and a DC bias circuit 22B. The attenuator 21B and the DC bias circuit 22B are connected to the same ground as the high-side drive circuit 20B. However, in a case where the voltage between the Kelvin source KS and the power source PS of the switching element 11B falls within an input range of the high-side drive circuit 20B, one or both of the attenuator 21B and the DC bias circuit 22B may be omitted. The drain of the switching element 11B is connected to the high-side drive circuit 20B through an attenuator 23B. The attenuator 23B is connected to the same ground as the high-side drive circuit 20B. However, in a case where a drain-source voltage of the switching element 11B falls within the input range of the high-side drive circuit 20B, the attenuator 23B may be omitted.

In the present embodiment, the grounds of the low-side drive circuit 20A and the high-side drive circuit 20B are separated from the ground GND of the half-bridge inverter. The switching elements 11A and 11B and the drive circuits 20A and 20B may be included in separate IC packages or may be included in the same IC package. The switching elements 11A and 11B and the drive circuits 20A and 20B may be mounted on different semiconductor substrates or may be mounted on the same semiconductor substrate.

The direction of a current (load current) Iload supplied from the half-bridge inverter to the load 60 is defined such that a direction in which the current flows from the half-bridge circuit 10 to the load 60 is positive, and a direction in which the current flows from the load 60 to the half-bridge circuit 10 is negative. However, this definition may be reversed.

The low-side drive circuit 20A supplies a gate current (low-side drive current) Ig_LS to the low-side switching element 11A in accordance with a low-side control signal IN_LS supplied from the control circuit 50. Specifically, when the low-side control signal IN_LS is “Hi”, the drive current Ig_LS flows from the drive circuit 20A toward the gate of the switching element 11A. In other words, the positive drive current Ig_LS is supplied from the drive circuit 20A to the switching element 11A. On the other hand, when the low-side control signal IN_LS is “Lo”, the drive current Ig_LS flows from the gate of the switching element 11A toward the drive circuit 20A. In other words, the negative drive current Ig_LS is supplied from the drive circuit 20A to the switching element 11A. Similarly, the high-side drive circuit 20B supplies a gate

current (high-side drive current) Ig_HS to the high-side switching element 11B in accordance with a high-side control signal IN_HS supplied from the control circuit 50. Specifically, when the high-side control signal IN_HS is “Hi”, the drive current Ig_HS flows from the drive circuit 20B toward the gate of the switching element 11B. In other words, the positive drive current Ig_HS is supplied from the drive circuit 20B to the switching element 11B. On the other hand, when the high-side control signal IN_HS is “Lo”, the drive current Ig_HS flows from the gate of the switching element 11B toward the drive circuit 20B. In other words, the negative drive current Ig_HS is supplied from the drive circuit 20B to the switching element 11B.

The control circuit 50 supplies the low-side control signal IN_LS to the low-side drive circuit 20A, and supplies the high-side control signal IN_HS to the high-side drive circuit 20B. The load 60 is an optional electronic apparatus or electric apparatus that is driven by alternating-current power. For example, in a case where the load 60 is an alternating-current motor, the control circuit 50 supplies the PWM-modulated low-side control signal IN_LS to the low-side drive circuit 20A, and supplies the PWM-modulated high-side control signal IN_HS to the high-side drive circuit 20B. Alternatively, the half-bridge inverter may be mounted in a power source apparatus such as a PV inverter for photovoltaic power generation. In this case, an output of the half-bridge circuit 10 is connected to a power grid in place of the load 60.

The low-side attenuator 21A is constituted by, for example, capacitors or resistors connected in series, and outputs a voltage obtained by dividing the voltage of the power source PS of the switching element 11A at a predetermined ratio. Specifically, when the voltage of the power source PS of the switching element 11A is denoted by Vps, an output voltage Va of the attenuator 21A is expressed by Expression (1) below.

$$\begin{matrix}[ Math . 1 ] & \\ {V}_{a} = α {V}_{p s} & ( 1 )\end{matrix}$$

In Expression (1) above, α is the division scale of the attenuator 21A and is set to a predetermined value within a range of 0<α<1.

The low-side DC bias circuit 22A is constituted by, for example, resistors and a constant-voltage source, and outputs a voltage obtained by adding a predetermined bias voltage Vbias to the output voltage Va of the attenuator 21A. Accordingly, an output voltage Vb of the DC bias circuit 22A is expressed by Expression (2) below.

$$\begin{matrix}[ Math . 2 ] & \\ {V}_{b} = {V}_{a} + {V}_{bias} = α {V}_{ps} + {V}_{bias} & ( 2 )\end{matrix}$$

As described above, the Kelvin source KS of the switching element 11A is connected to the ground of the low-side drive circuit 20A. Thus, for the low-side drive circuit 20A, the voltage Vps of the power source PS of the switching element 11A is equal to a voltage VIs that occurs across both ends of the parasitic inductance Ls of the switching element 11A.

The attenuator 21A and the DC bias circuit 22A are connected to the same ground as the low-side drive circuit 20A. Accordingly, a voltage Vfb_LS input to the low-side drive circuit 20A through the attenuator 21A and the DC bias circuit 22A is expressed by Expression (3) below by using the voltage VIs (=Vps) that occurs across both ends of the parasitic inductance Ls of the switching element 11A.

$$\begin{matrix}[ Math . 3 ] & \\ {V}_{fb} \_ LS = α {V}_{ls} + {V}_{bias} & ( 3 )\end{matrix}$$

The voltage VIs that occurs across both ends of the parasitic inductance Ls of the switching element 11A is caused by a temporal change of a drain current (output current) Id_LS of the switching element 11A, and the following relational expression (4) holds between the voltage VIs and the drain current Id_LS.

$$\begin{matrix}[ Math . 4 ] & \\ {V}_{l s} = - {L}_{s} \frac{d ( {I}_{{d}_{-}} L S )}{d t} & ( 4 )\end{matrix}$$

The following relational expression (5) is obtained by substituting Expression (4) into Expression (3).

$$\begin{matrix}[ Math . 5 ] & \\ {V}_{fb -} LS = - α {L}_{s} \frac{d ( {I}_{{d}_{-}} L S )}{d t} + {V}_{b i a s} & ( 5 )\end{matrix}$$

Expression (5) above indicates that the voltage Vfb_LS input to the low-side drive circuit 20A is a physical quantity corresponding to a temporal change (i.e., a time rate of change) of the output current Id_LS of the switching element 11A. In other words, the low-side drive circuit 20A can acquire the voltage Vfb_LS as a physical quantity corresponding to a temporal change of the output current Id_LS of the switching element 11A.

However, a physical quantity corresponding to a temporal change of the output current Id_LS of the switching element 11A is not limited thereto. For example, a physical quantity corresponding to a temporal change of the output current Id_LS may be acquired by connecting a shunt resistor to the power source PS of the switching element 11A and passing a voltage that occurs across both ends of the shunt resistor through a high-pass filter that functions as a differentiator.

The low-side attenuator 23A is constituted by, for example, capacitors or resistors connected in series, and outputs a voltage obtained by dividing a drain voltage of the switching element 11A at a predetermined ratio. Accordingly, an output voltage Vfc_LS of the attenuator 23A is expressed by Expression (6) below by using a drain-source voltage (output voltage) Vds_LS of the switching element 11A.

$$\begin{matrix}[ Math . 6 ] & \\ {V}_{fc} \_ LS -= γ {V}_{ds} \_ LS & ( 6 )\end{matrix}$$

In Expression (6) above, γ is the division scale of the attenuator 23A and is set to a predetermined value within a range of 0<γ<1.

Expression (6) above indicates that the voltage Vfc_LS input to the low-side drive circuit 20A is a voltage corresponding to the output voltage Vds_LS of the switching element 11A. In other words, the low-side drive circuit 20A can acquire the voltage Vfc_LS as a physical quantity corresponding to the output voltage Vds_LS of the switching element 11A.

The above-described discussion similarly applies to the high-side drive circuit 20B. Accordingly, the high-side drive circuit 20B can acquire a voltage Vfb_HS as a physical quantity corresponding to a temporal change of an output current Id_HS of the switching element 11B. In addition, the high-side drive circuit 20B can acquire a voltage Vfc_HS as a physical quantity corresponding to an output voltage Vds_HS of the switching element 11B.

### Operation of Switching Element During Turn-on

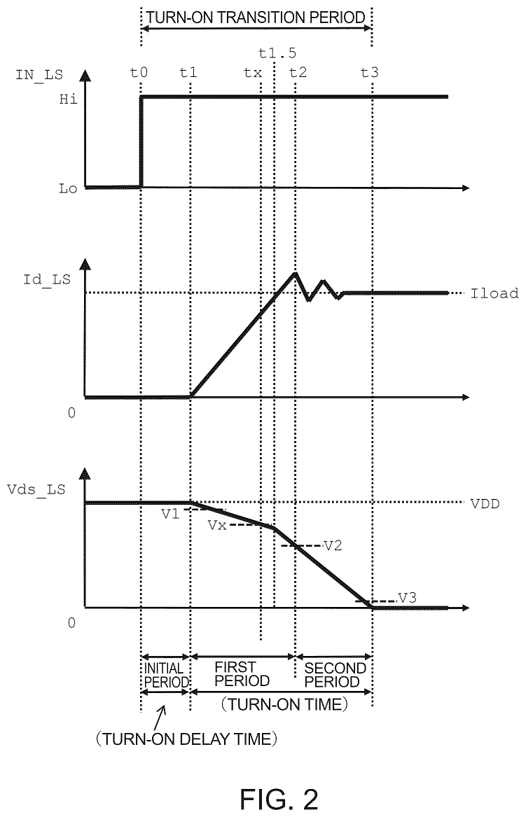

FIG. 2 is a diagram illustrating an operation of the switching element 11A during turn-on. The uppermost time waveform is the time waveform of the low-side control signal IN_LS. The second time waveform is the time waveform of the drain current Id_LS of the switching element 11A. The third time waveform is the time waveform of the drain-source voltage Vds_LS of the switching element 11A. Note that meanings of V1 to V1 and Vx in the drawing will be described together in description of a turn-on current command circuit to be described later.

At time point t0, the control signal IN_LS changes from “Lo” to “Hi”, and supply of the drive current Ig_LS from the low-side drive circuit 20A to the switching element 11A is started. Accordingly, a gate-source voltage Vgs (not illustrated) of the switching element 11A starts to increase.

At time point t1, when the gate-source voltage Vgs exceeds a threshold voltage, the drain current Id_LS starts to flow, and the drain-source voltage Vds_LS starts to decrease. At time point t2, the surge of the drain current Id_LS reaches a maximum value. At time point t3, the drain-source voltage Vds_LS becomes a minimum value, that is, zero.

In the present embodiment, a turn-on transition period (time point t0 to time point t3 in FIG. 2) is divided into three periods, namely “initial period (time point t0 to time point t1)”, “first period (time point t1 to time point t2)”, and “second period (time point t2 to time point t3)”. The initial period corresponds to a turn-on delay time. The sum of the first period and the second period corresponds to a turn-on time.

The initial period is a period (time point t0 to time point t1 in FIG. 2) from when the control signal IN_LS becomes “Hi” and supply of the drive current Ig_LS is started to when the drain current Id_LS starts to flow. This period is a period in which a gate-source capacitance Cgs (not illustrated) and a gate-drain capacitance Cgd (not illustrated) of the switching element 11A are charged by the drive current Ig_LS, and the drain-source voltage Vds_LS does not change.

The first period is a period (time point t1 to time point t2 in FIG. 2) from when the drain current Id_LS starts to flow to when the drain current Id_LS reaches a maximum value. A temporal change of the drain-source voltage Vds_LS in the first half of the first period, more precisely, a temporal change of the drain-source voltage Vds_LS from when the drain current Id_LS starts to flow to when the drain current Id_LS becomes equal to the load current Iload (time point t1 to time point t1.5 in FIG. 2) is approximately expressed by Expression (7) below.

$$\begin{matrix}[ Math . 7 ] & \\ {V}_{ds -} LS ( t ) = {V}_{D D} - {L}_{s} \frac{d ( {I}_{d -} LS )}{d t} & ( 7 )\end{matrix}$$

In Expression (7) above, V_{DD} is a power voltage of the half-bridge inverter, and Ls is a parasitic inductance of the switching element 11A.

The second period is a period from when the drain current Id_LS reaches a maximum value to when the drain-source voltage Vds_LS becomes a minimum value, that is, zero (time point t2 to time point t3 in FIG. 2). A temporal change of the drain-source voltage Vds_LS from when the drain current Id_LS becomes equal to the load current Iload in the second half of the first period to the end of the second period (time point t1.5 to time point t3 in FIG. 2) is approximately expressed by Expression (8) below.

$$\begin{matrix}[ Math . 8 ] & \\ {V}_{d s -} L S ( t ) = {V}_{d s 0} - ( \frac{{I}_{g -} L S}{{C}_{g d}} ) t & ( 8 )\end{matrix}$$

In Expression (8) above, Vds0 is a drain-source voltage when the drain current Id_LS becomes equal to the load current Iload (t1.5 in FIG. 2), and Cgd is the gate-drain capacitance (not illustrated) of the switching element 11A.

### Operation of Switching Element During Turn-Off

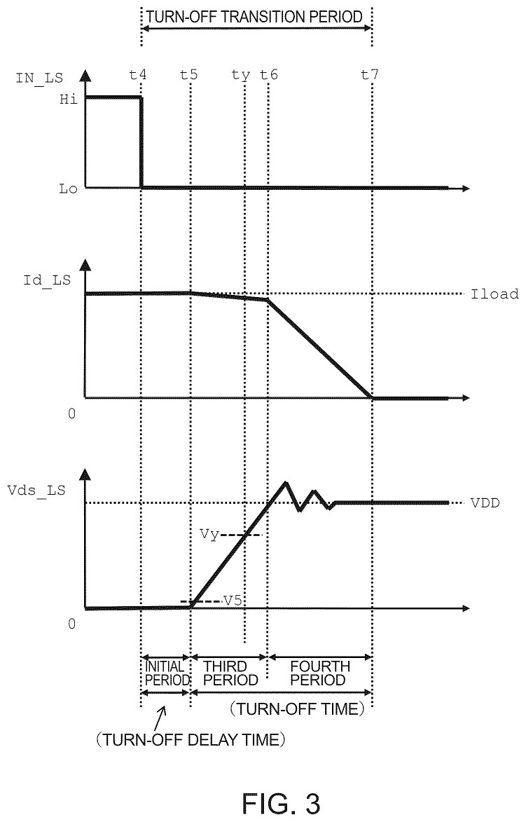

FIG. 3 is a diagram illustrating an operation of the switching element 11A during turn-off. The uppermost time waveform is the time waveform of the low-side control signal IN_LS. The second time waveform is the time waveform of the drain current Id_LS of the switching element 11A. The third time waveform is the time waveform of the drain-source voltage Vds_LS of the switching element 11A. Note that meanings of V5 and Vy in the drawing will be described together in description of a turn-off current command circuit to be described later.

At time point t4, the control signal IN_IS changes “Hi” to “Lo”, and supply of the drive current Ig_LS from the switching element 11A toward the low-side drive circuit 20A, that is, the negative drive current Ig_LS (<0) is started. Accordingly, the gate-source voltage Vgs (not illustrated) of the switching element 11A starts to decrease.

At time point t5, the drain-source voltage Vds_LS starts to increase, and a drain current Id starts to slightly decrease. At time point t6, when the drain-source voltage Vds_LS becomes equal to the power voltage VDD, the drain current Id_LS starts to substantially decrease. At time point t7, the drain current Id_LS becomes a minimum value, that is, zero.

In the present embodiment, a turn-off transition period (period from time point t4 to time point t7 in FIG. 3) is divided into three periods, namely “initial period (time point t4 to time point t5)”, “third period (time point t5 to time point t6)”, and “fourth period (time point t6 to time point t7)”. The initial period corresponds to a turn-off delay time. The sum of the third period and the fourth period corresponds to a turn-off time.

The initial period is a period (time point t4 to time point t5 in FIG. 3) from the control signal IN_LS becomes “Lo” and supply of the negative drive current Ig_LS is started to when the drain voltage Vds_LS starts to increase. This period is a period in which the gate-source capacitance Cgs (not illustrated) and the gate-drain capacitance Cgd (not illustrated) of the switching element 11A are discharged by the negative drive current Ig_LS, and the drain-source voltage Vds_LS does not change.

The third period is a period (time point t5 to time point t6 in FIG. 3) from when the drain-source voltage Vds_LS starts to increase to when the drain current Id_LS starts to substantially decrease. The fourth period is a period (time point t6 to time point t7 in FIG. 3) from when the drain current Id_LS starts to substantially decrease to when the drain current Id_LS becomes zero.

### Configuration of Drive Circuit

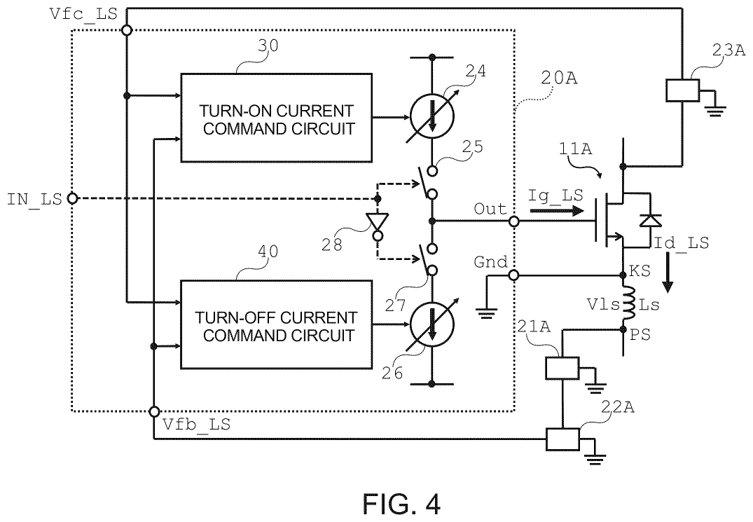

FIG. 4 is a diagram illustrating a detailed configuration of the low-side drive circuit 20A. Note that the high-side drive circuit 20B has the same configuration, and thus the following description will be made only on the configuration of the low-side drive circuit 20A. The low-side drive circuit 20A includes a turn-on current command circuit 30, a turn-off current command circuit 40, a first variable current source 24, a first switch 25, a second variable current source 26, a second switch 27, and a NOT gate 28. The constituent components 24 to 28 constitute a current supply circuit of the low-side drive circuit 20A. The low-side drive circuit 20A and the high-side drive circuit 20B are implemented by electronic circuitry.

The turn-on current command circuit 30 determines, based on the voltage Vfb_LS and the voltage Vfc_LS, a value of the drive current Ig_LS to be supplied during the turn-on transition period of the switching element 11A, and outputs a current value (command value) corresponding to the determined value of the drive current Ig_LS to the first variable current source 24. The first variable current source 24 outputs a current in accordance with the current value specified by the turn-on current command circuit 30. The first switch 25 is turned on only when the control signal IN_LS is “Hi”. Accordingly, during turn-on of the switching element 11A, the low-side drive circuit 20A outputs the drive current Ig_LS in accordance with the current value (command value) specified by the turn-on current command circuit 30.

Similarly, the turn-off current command circuit 40 determines, based on the voltage Vfb_LS and the voltage Vfc_LS, a current value of the drive current Ig_LS to be supplied during the turn-off transition period of the switching element 11A, and outputs the current value to the second variable current source 26. The second variable current source 26 outputs a current in accordance with the current value (command value) specified by the turn-off current command circuit 40. The second switch 27 is turned on only when the control signal IN_LS is “Lo”. Accordingly, during turn-off of the switching element 11A, the low-side drive circuit 20A outputs the drive current Ig_LS in accordance with the current value (command value) specified by the turn-off current command circuit 40.

### Configuration of Turn-on Current Command Circuit

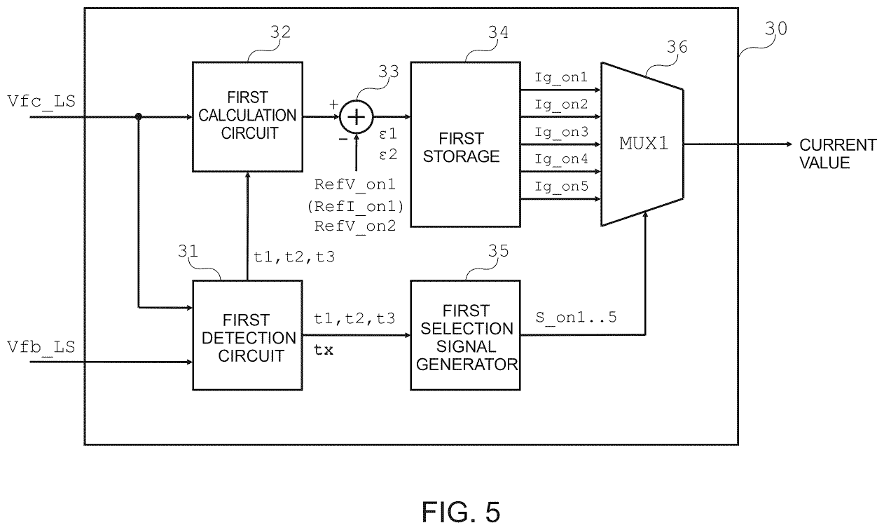

FIG. 5 is a diagram illustrating a detailed configuration of the turn-on current command circuit 30. The turn-on current command circuit 30 includes a first detection circuit 31, a first calculation circuit 32, a first adder 33, a first storage 34, a first selection signal generator 35, and a first multiplexer 36. The constituent components 33 to 36 constitute part of a controller of the low-side drive circuit 20A.

The first detection circuit 31 detects transition timings (time point t1 to time point t3 in FIG. 2) and a preliminary timing (time point tx in FIG. 2) during the turn-on transition period of the switching element 11A based on the voltage Vfb_LS, which is a physical quantity corresponding to a temporal change of the drain current Id_LS of the switching element 11A, and the voltage Vfc_LS, which is a physical quantity corresponding to the drain-source voltage Vds_LS of the switching element 11A.

Specifically, the first detection circuit 31 detects a first transition timing (t1) by detecting a timing at which the voltage Vfc_LS becomes lower than a predetermined voltage Vt_on1. The predetermined voltage Vt_on1 is defined by Expression (9) below by using a voltage V1 that is slightly lower than the power voltage VDD indicated in the graph of the drain-source voltage Vds_LS in FIG. 2.

$$\begin{matrix}[ Math . 9 ] & \\ {V}_{t \_ on 1} = γ {V}_{1} & ( 9 )\end{matrix}$$

In Expression (9) above, Y is the division scale of the attenuator 23A.

Alternatively, the first detection circuit 31 may detect the first transition timing (t1) by detecting a timing at which the voltage Vfb_LS corresponding to the gradient of the drain current Id_LS changes from zero to a positive value.

The first detection circuit 31 detects a preliminary timing (tx) by detecting a timing at which the voltage Vfc_LS becomes lower than a predetermined voltage Vt_onX. The preliminary timing (tx) means that the timing is earlier than a second transition timing (t2) to be described next. For example, the predetermined voltage Vt_onX is defined by Expression (10) below by using a voltage Vx indicated in the graph of the drain-source voltage Vds_LS in FIG. 2.

$$\begin{matrix}[ Math . 10 ] & \\ {V}_{t \_ on X} = γ {V}_{x} & ( 10 )\end{matrix}$$

In Expression (10) above, γ is the division scale of the attenuator 23A.

Alternatively, the first detection circuit 31 may detect the preliminary transition timing (tx) as a timing at which a predetermined delay time has elapsed since detection of the first transition timing (t1). In this case, the delay time is experimentally determined in advance.

The first detection circuit 31 detects the second transition timing (t2) by detecting a timing at which the voltage Vfc_LS becomes lower than a predetermined voltage Vt_on2. The predetermined voltage Vt_on2 is defined by Expression (11) below by using a voltage V2 indicated in the graph of the drain-source voltage Vds_LS in FIG. 2.

$$\begin{matrix}[ Math . 11 ] & \\ {V}_{t \_ on 2} = γ {V}_{2} & ( 11 )\end{matrix}$$

In Expression (11) above, γ is the division scale of the attenuator 23A.

Alternatively, the first detection circuit 31 may detect the second transition timing (t2) by detecting a timing at which the voltage Vfb_LS corresponding to the gradient of the drain current Id_LS changes from a positive value to a negative value.

The first detection circuit 31 detects a third transition timing (t3) by detecting a timing at which the voltage Vfc_LS becomes lower than a predetermined voltage Vt_on3. The predetermined voltage Vt_on3 is defined by Expression (12) below by using a voltage V3 that is slightly higher than zero, which is indicated in the graph of the drain-source voltage Vds_LS in FIG. 2.

$$\begin{matrix}[ Math . 12 ] & \\ {V}_{t \_ on 3} = γ {V}_{3} & ( 12 )\end{matrix}$$

In Expression (12) above, γ is the division scale of the attenuator 23A.

The first calculation circuit 32 calculates, based on the voltage Vfc_LS corresponding to the drain-source voltage Vds_LS of the switching element 11A, a slew rate (first voltage slew rate) SRV_on1 of the drain-source voltage Vds_LS of the switching element 11A in the first period (time point t1 to time point t2 in FIG. 2), which is defined by Expression (13) below.

$$\begin{matrix}[ Math . 13 ] & \\ SRV\_on1 = \frac{{V}_{ds \_} L S ( {t}_{2} ) - {V}_{d {s}_{-}} L S ( {t}_{1} )}{{t}_{2} - {t}_{1}} & ( 13 )\end{matrix}$$

Alternatively, the first calculation circuit 32 may calculate, based on the voltage Vfb_LS corresponding to a temporal change of the drain current Id_LS of the switching element 11A, a slew rate (first current slew rate) SRI_on1 of the drain current Id_LS of the switching element 11A in the first period, which is defined by Expression (14) below.

$$\begin{matrix}[ Math . 14 ] & \\ SRI\_on1 = \frac{Id\_LS ( {t}_{2} ) - Id\_LS ( {t}_{1} )}{{t}_{2} - {t}_{1}} & ( 14 )\end{matrix}$$

The first calculation circuit 32 also calculates, based on the voltage Vfc_LS corresponding to the drain-source voltage Vds_LS of the switching element 11A, a slew rate (second voltage slew rate) SRV_on2 of the drain-source voltage Vds_LS of the switching element 11A in the second period (time point t2 to time point t3 in FIG. 2), which is defined by Expression (15) below.

$$\begin{matrix}[ Math . 15 ] & \\ SRV\_on2 = \frac{{V}_{d {s}_{-}} L S ( {t}_{3} ) - {V}_{d {s}_{-}} L S ( {t}_{2} )}{{t}_{3} - {t}_{2}} & ( 15 )\end{matrix}$$

The first adder 33 calculates a deviation ε1 between the first voltage slew rate SRV_on1 output from the first calculation circuit 32 and a predetermined target value RefV_on1. Alternatively, the first adder 33 may calculate a deviation 1 between the first current slew rate SRI_on1 output from the first calculation circuit 32 and a predetermined target value RefI_on1. The first adder 33 also calculates a deviation ε2 between the second voltage slew rate SRV_on2 output from the first calculation circuit 32 and a predetermined target value RefV_on2.

The first storage 34 stores five kinds of positive current values Ig_on1 to Ig_on5. The following relational expression (16) holds among the current values Ig_on1 to Ig_on3.

$$\begin{matrix}[ Math . 16 ] & \\ {I}_{g \_ on 2} \leq {I}_{g \_ on 1} , {I}_{g \_ on 3} \leq {I}_{g \_ on 1} & ( 16 )\end{matrix}$$

The current values Ig_on4 and Ig_on5 may be the same value or different values. The current values Ig_on4 and Ig_on5 may be the same value as any one of the above-described current values Ig_on1 to Ig_on3, or may be different values.

The first selection signal generator 35 outputs any one of five kinds of selection signals S_on1 to S_on5 corresponding to the respective current values Ig_on1 to Ig_on5 to the first multiplexer 36 in accordance with the transition timings (t1 to t3) and the preliminary timing (tx) detected by the first detection circuit 31.

Specifically, the first selection signal generator 35 outputs the selection signal S_on1 in an initial state at start of turn-on (to), outputs the selection signal S_on2 when the first transition timing (t1) is detected, outputs the selection signal S_on3 when the second transition timing (t2) is detected, and outputs the selection signal S_on4 when the third transition timing (t3) is detected. The first selection signal generator 35 outputs the selection signal S_on5 when the preliminary timing (tx) is detected.

In accordance with a selection signal input from the first selection signal generator, the first multiplexer 36 selects any one of the current values Ig_on1 to Ig_on5 stored in the first storage 34, and outputs the selected current value. Specifically, the first multiplexer 36 selects and outputs the current value Ig_on1 when the selection signal S_on1 is input, selects and outputs the current value Ig_on2 when the selection signal S_on2 is input, selects and outputs the current value Ig_on3 when the selection signal S_on3 is input, selects and outputs the current value Ig_on4 when the selection signal S_on4 is input, and selects and outputs the current value Ig_on5 when the selection signal S_on5 is input.

### Operation of Drive Circuit During Turn-on

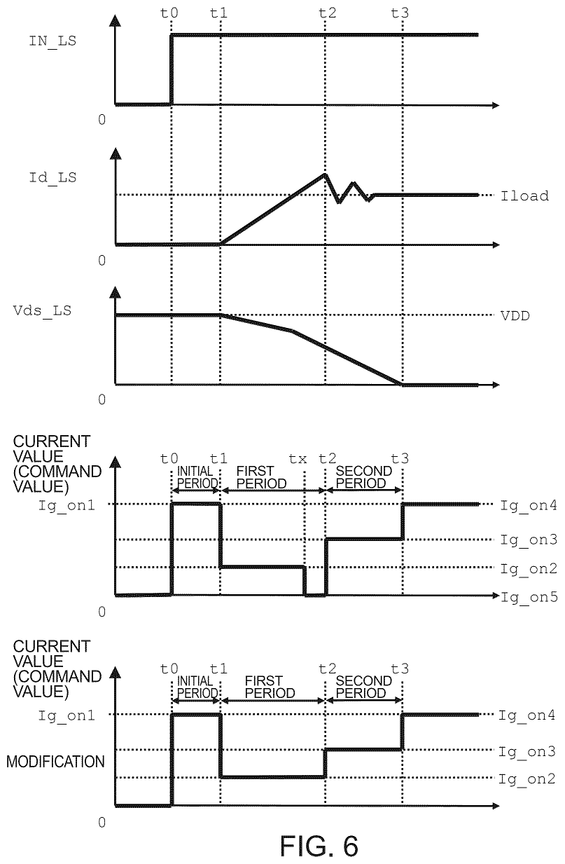

FIG. 6 is a diagram for description of an operation of the low-side drive circuit 20A according to Embodiment 1 during turn-on. Note that the high-side drive circuit 20B performs the same operation, and thus the following description will be made only on the operation of the low-side drive circuit 20A. The uppermost time waveform is the time waveform of the low-side control signal IN_LS. The second time waveform is the time waveform of the drain current Id_LS of the switching element 11A. The third time waveform is the time waveform of the drain-source voltage Vds_LS of the switching element 11A. The fourth time waveform is the time waveform of a current value (command value) for the low-side drive current Ig_LS. The fifth time waveform is the time waveform of a current value (command value) for the low-side drive current Ig_LS according to a modification of Embodiment 1.

At time point t0, when the control signal IN_LS changes from “Lo” to “Hi”, the low-side drive circuit 20A starts supply of the drive current Ig_LS having the predetermined current value Ig_on1. Specifically, in an initial state at start of turn-on (t0), the first selection signal generator 35 outputs the selection signal S_on1 to the first multiplexer 36. The first multiplexer 36 selects and outputs the current value Ig_on1 stored in the first storage 34, and the first variable current source 24 outputs a current in accordance with the current value Ig_on1. Accordingly, when the control signal IN_LS becomes “Hi” at time point t0, the first switch 25 is turned on, and supply of the drive current Ig_LS from the low-side drive circuit 20A in accordance with the current value Ig_on1 is started. In order to shorten a turn-on delay time (t0 to t1) of the switching element 11A, it is preferable that the absolute value of the current Ig_on1 be as large as possible within a range in which an operation of the switching element 11A is stable. For example, the current value Ig_on1 may be a value corresponding to a maximum current value that the first variable current source 24 can output in the positive direction (forward direction from the drive circuit 20A to the switching element 11A).

At time point t1, when the drain current Id_LS starts to flow and the drain-source voltage Vds_LS starts to decrease, the low-side drive circuit 20A switches the current value for the drive current Ig_LS to the current value Ig_on2 that is smaller than the current value Ig_on1 so as to control the voltage slew rate or the current slew rate in the first period (t1 to t2). Specifically, when the first transition timing (t1) is detected by the first detection circuit 31, the first selection signal generator 35 outputs the selection signal S_on2 to the first multiplexer 36. Accordingly, the first multiplexer 36 selects and outputs the current value Ig_on2 stored in the first storage 34, and the first variable current source 24 outputs a current in accordance with the current value Ig_on2.

At time point tx, the low-side drive circuit 20A switches the current value for the drive current Ig_LS to the predetermined current value Ig_on5 that is further smaller than the current value Ig_on2 so as to suppress the surge of the drain current Id_LS. Specifically, when the preliminary timing (tx) is detected by the first detection circuit 31, the first selection signal generator 35 outputs the selection signal S_on5 to the first multiplexer 36. Accordingly, the first multiplexer 36 selects and outputs the current value Ig_on5 stored in the first storage 34, and the first variable current source 24 outputs a current in accordance with the current value Ig_on5. In order to suppress the surge of the drain current Id_LS, it is preferable that the absolute value of the current value Ig_on5 be as small as possible within a range in which an operation of the switching element 11A is stable. However, when the current value Ig_on5 is excessively small, the first period (t1 to t2) is long. The current value Ig_on5 is experimentally determined in advance to be a predetermined value that is smaller than the current value Ig_on2 in consideration of a trade-off therebetween. For example, the current value Ig_on5 may be zero or a positive value close to zero.

At time point t2, when the drain current Id_LS reaches a maximum value, the low-side drive circuit 20A switches the current value for the drive current Ig_LS to the current value Ig_on3 that is smaller than the current value Ig_on1 so as to control the voltage slew rate in the second period (t2 to t3). Specifically, when the second transition timing (t2) is detected by the first detection circuit 31, the first selection signal generator 35 outputs the selection signal S_on3 to the first multiplexer 36. Accordingly, the first multiplexer 36 selects and outputs the current value Ig_on3 stored in the first storage 34, and the first variable current source 24 outputs a current in accordance with the current value Ig_on3.

At time point t2 or later, the first calculation circuit 32 calculates, based on the voltage Vfc_LS and the transition timings (t1 and t2) detected by the first detection circuit 31, the slew rate (first voltage slew rate) SRV_on1 of a drain-source voltage Vds defined by Expression (13) described above.

The first adder 33 calculates the deviation ε1 between the first voltage slew rate SRV_on1 calculated by the first calculation circuit 32 and the predetermined target value RefV_on1. The first storage 34 corrects (overwrites) the current value Ig_on2 stored in itself in accordance with the deviation ε1 calculated by the first adder 33.

Specifically, when the absolute value of the first voltage slew rate SRV_on1 in the n-th turn-on duration is larger than the absolute value of the target value RefV_on1, the first storage 34 corrects the current value Ig_on2 stored in itself to a smaller value in accordance with the deviation ε1. Accordingly, the current value Ig_on2 selected and output by the first multiplexer 36 in the next (n+1)-th turn-on duration becomes smaller than the current value in the n-th turn-on duration. As a result, the drive current Ig_LS output from the first variable current source 24 in the first period in the next (n+1)-th turn-on duration becomes smaller than the drive current in the n-th turn-on duration.

On the other hand, when the absolute value of the first voltage slew rate SRV_on1 in the n-th turn-on duration is smaller than the absolute value of the target value RefV_on1, the first storage 34 corrects the current value Ig_on2 stored in itself to a larger value in accordance with the deviation ε1. Accordingly, the current value Ig_on2 selected and output by the first multiplexer 36 in the next (n+1)-th turn-on duration becomes larger than the current value in the n-th turn-on duration. As a result, the drive current Ig_LS output from the first variable current source 24 in the first period in the next (n+1)-th turn-on duration becomes larger than the drive current in the n-th turn-on duration.

As described above, the current value Ig_on2 for the drive current in the first period is controlled so that the first voltage slew rate SRV_on1 matches the target value RefV_on1.

Alternatively, the first calculation circuit 32 may calculate the slew rate (first current slew rate) SRI_on1 of the drain current Id_LS, which is defined by Expression (14) described above, based on the voltage Vfb_LS and the transition timings (time points t1 and t2) detected by the first detection circuit 31.

The first adder 33 calculates the deviation ε1 between the first current slew rate SRI_on1 calculated by the first calculation circuit 32 and the predetermined target value RefI_on1. The first storage 34 corrects (overwrites) the current value Ig_on2 stored in itself in accordance with the deviation ε1 calculated by the first adder 33. Accordingly, the current value Ig_on2 for the drive current in the first period is controlled so that the first current slew rate SRI_on1 matches the target value RefI_on1.

At time point t3, when the drain-source voltage Vds_LS becomes zero, the low-side drive circuit 20A switches the current value for the drive current Ig_LS to the predetermined current value Ig_on4 so as to prevent an unexpected malfunction during an on-period of the switching element 11A. Specifically, when the third transition timing (t3) is detected by the first detection circuit 31, the first selection signal generator 35 outputs the selection signal S_on4 to the first multiplexer 36. Accordingly, the first multiplexer 36 selects and outputs the current value Ig_on4 stored in the first storage 34, and the first variable current source 24 outputs a current in accordance with the current value Ig_on4. In order to prevent the switching element 11A from being turned off due to a malfunction, it is preferable that the current Ig_on4 be as large as possible within a range in which an operation of the switching element 11A is stable. For example, the current value Ig_on4 may be a value in accordance with a maximum current value that the first variable current source 24 can output in the positive direction (forward direction from the drive circuit 20A to the switching element 11A).

At time point t3 or later, the first calculation circuit 32 calculates the slew rate (second voltage slew rate) SRV_on2 of the drain-source voltage Vds, which is defined by Expression (15) described above, based on the voltage Vfc_LS and the transition timings (time points t2 and t3) detected by the first detection circuit 31.

The first adder 33 calculates the deviation ε2 between the second voltage slew rate SRV_on2 calculated by the first calculation circuit 32 and the predetermined target value RefV_on2. The first storage 34 corrects (overwrites) the current value Ig_on3 stored in itself in accordance with the deviation ε2 calculated by the first adder 33.

Specifically, when the absolute value of the second voltage slew rate SRV_on2 in the n-th turn-on duration is larger than the absolute value of the predetermined target value RefV_on2, the first storage 34 corrects the current value Ig_on3 stored in itself to a smaller value in accordance with the deviation ε2. On the other hand, when the absolute value of the second voltage slew rate SRV_on2 in the n-th turn-on duration is smaller than the absolute value of the target value RefV_on2, the first storage 34 corrects the current value Ig_on3 stored in itself to a larger value in accordance with the deviation ε2. Accordingly, the current value Ig_on3 for the drive current in the second period is controlled so that the second voltage slew rate SRV_on2 matches the target value RefV_on2.

The drive current Ig_LS of the switching element 11A during turn-on is controlled as described above. Note that, as a modification, when suppression of the surge of the drain current Id_LS is not required, the first detection circuit 31 may omit detection of the preliminary timing (tx). In this case, the time waveform of the current value (command value) for the drive current Ig_LS is as illustrated in the fifth graph in FIG. 6.

### Configuration of Turn-Off Current Command Circuit

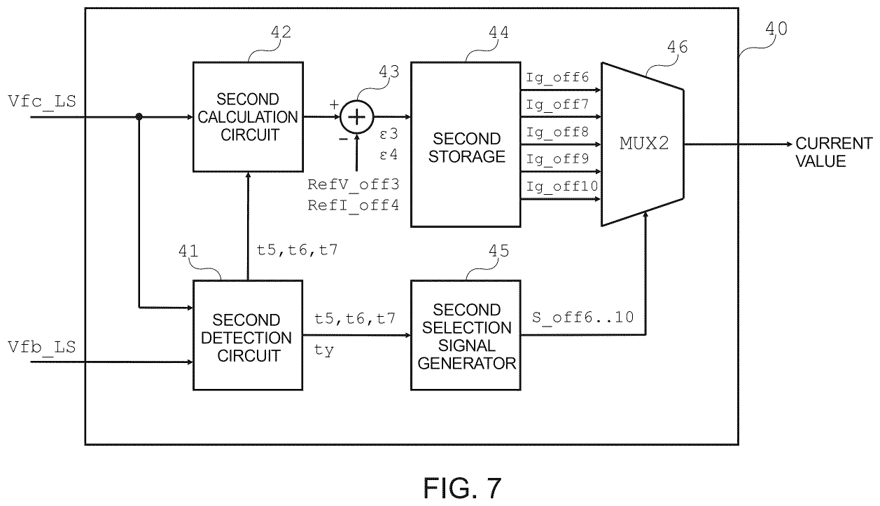

FIG. 7 is a diagram illustrating a detailed configuration of the turn-off current command circuit 40. The turn-off current command circuit 40 includes a second detection circuit 41, a second calculation circuit 42, a second adder 43, a second storage 44, a second selection signal generator 45, and a second multiplexer 46. The constituent components 43 to 46 constitute part of the controller of the low-side drive circuit 20A.

The second detection circuit 41 detects transition timings (time point t5 to time point t7 in FIG. 3) and a preliminary timing (time point ty in FIG. 3) during the turn-off transition period of the switching element 11A based on the voltage Vfb_LS, which is a physical quantity corresponding to a temporal change of the drain current Id_LS of the switching element 11A, and the voltage Vfc_LS, which is a physical quantity corresponding to the drain-source voltage Vds_LS of the switching element 11A.

Specifically, the second detection circuit 41 detects a fifth transition timing (t5) by detecting a timing at which the voltage Vfc_LS exceeds a predetermined voltage Vt_off5. The predetermined voltage Vt_off5 is defined by Expression (17) below by using a voltage V5 that is slightly higher than zero, which is indicated in the graph of the drain-source voltage Vds_LS in FIG. 3.

$$\begin{matrix}[ Math . 17 ] & \\ {V}_{t \_ off 5} = γ {V}_{5} & ( 17 )\end{matrix}$$

In Expression (17) above, γ is the division scale of the attenuator 23A.

The second detection circuit 41 detects a preliminary timing (ty) by detecting a timing at which the voltage Vfc_LS exceeds a predetermined voltage Vt_offY. The preliminary timing (ty) means that the timing is earlier than a sixth transition timing (t6) to be described next. For example, the predetermined voltage Vt_offY is defined by Expression (18) below by using a voltage Vy indicated in the graph of the drain-source voltage Vds_LS in FIG. 3.

$$\begin{matrix}[ Math . 18 ] & \\ {V}_{t \_ off Y} = γ {V}_{y} & ( 18 )\end{matrix}$$

In Expression (18) above, γ is the division scale of the attenuator 23A.

Alternatively, the second detection circuit 41 may detect the preliminary transition timing (ty) as a timing at which a predetermined delay time has elapsed since detection of the fifth transition timing (t5). In this case, the delay time is experimentally determined in advance.

The second detection circuit 41 detects the sixth transition timing (t6) by detecting a timing at which the voltage Vfc_LS becomes equal to or greater than the product of the power voltage V_{DD} and the division scale γ of the attenuator 23A, that is, a voltage γVDD (predetermined voltage). Alternatively, the second detection circuit 41 may detect the sixth transition timing (t6) by detecting a timing at which the voltage Vfb_LS corresponding to the gradient of the drain current Id_LS abruptly changes from a negative value close to zero to a large negative value.

The second detection circuit 41 detects a seventh transition timing (t7) by detecting a timing at which the voltage Vfb_LS corresponding to the gradient of the drain current Id_LS changes from a negative value to zero.

The second calculation circuit 42 calculates a slew rate (third voltage slew rate) SRV_off3 of the drain-source voltage Vds_LS of the switching element 11A in the third period (time point t5 to time point t6 in FIG. 3), which is defined by Expression (19) below, based on the voltage Vfc_LS corresponding to the drain-source voltage Vds_LS of the switching element 11A.

$$\begin{matrix}[ Math . 19 ] & \\ SRV\_off 3 = \frac{{V}_{ds \_ LS} ( {t}_{6} ) - {V}_{ds \_ LS} ( {t}_{5} )}{{t}_{6} - {t}_{5}} & ( 19 )\end{matrix}$$

The second calculation circuit 42 also calculates a slew rate (fourth current slew rate) SRI_off4 of the drain current Id_LS of the switching element 11A in the fourth period (time point t6 to time point t7 in FIG. 3), which is defined by Expression (20) below, based on the voltage Vfb_LS corresponding to the drain current Id_LS of the switching element 11A.

$$\begin{matrix}[ Math . 20 ] & \\ SRI\_off4 = \frac{Id\_LS ( {t}_{7} ) - Id\_LS ( {t}_{6} )}{{t}_{7} - {t}_{6}} & ( 20 )\end{matrix}$$

The second adder 43 calculates a deviation ε3 between the third voltage slew rate SRV_off3 output from the second calculation circuit 42 and a predetermined target value RefV_off3. The second adder 43 also calculates a deviation ε4 between the fourth current slew rate SRI_off4 output from the second calculation circuit 42 and a predetermined target value RefI_off4.

The second storage 44 stores five kinds of negative current values Ig_off6 to Ig_off10. The following relational expression (21) holds among the current values Ig_off6 to Ig_off8.

$$\begin{matrix}[ Math . 21 ] & \\ {I}_{g\_off 6} \leq {I}_{g\_off 8} , {I}_{g\_off 6} \leq {I}_{g\_off 7} & ( 21 )\end{matrix}$$

The current values Ig_off9 and Ig_off10 may be the same value or different values. The current values Ig_off9 and Ig_off10 may be the same value as any one of the above-described current values Ig_off6 to Ig_off8, or may be different values.

The second selection signal generator 45 outputs any one of five kinds of selection signals S_off6 to S_off10 corresponding to the respective current values Ig_off6 to Ig_off10 to the second multiplexer 46 in accordance with the transition timings (t5 to t7) and the preliminary timing (ty) detected by the second detection circuit 41.

Specifically, the second selection signal generator 45 outputs the selection signal S_off6 in an initial state at start of turn-off (t4), outputs the selection signal S_off7 when the fifth transition timing (t5) is detected, outputs the selection signal S_off8 when the sixth transition timing (t6) is detected, and outputs the selection signal S_off9 when the seventh transition timing (t7) is detected. The second selection signal generator 45 outputs the selection signal S_off10 when the preliminary timing (ty) is detected.

In accordance with a selection signal input from the second selection signal generator 45, the second multiplexer 46 selects and outputs any one of the current values Ig_off6 to Ig_off10 stored in the second storage 44. Specifically, the second multiplexer 46 selects and outputs the current value Ig_off6 when the selection signal S_off6 is input, selects and outputs the current value Ig_off7 when the selection signal S_off7 is input, selects and outputs the current value Ig_off8 when the selection signal S_off8 is input, selects and outputs the current value Ig_off9 when the selection signal S_off9 is input, and selects and outputs the current value Ig_off10 when the selection signal S_off10 is input.

### Operation of Drive Circuit During Turn-Off

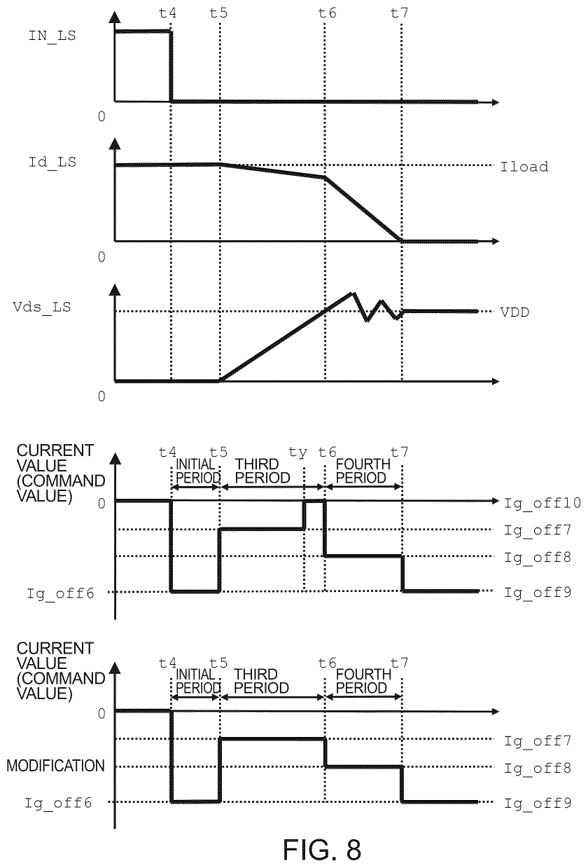

FIG. 8 is a diagram for description of an operation of the low-side drive circuit 20A according to Embodiment 1 duration turn-off. Note that the high-side drive circuit 20B performs the same operation, and thus the following description will be made only on the operation of the low-side drive circuit 20A. The uppermost time waveform is the time waveform of the low-side control signal IN_LS. The second time waveform is the time waveform of the drain current Id_LS of the switching element 11A. The third time waveform is the time waveform of the drain-source voltage Vds_LS of the switching element 11A. The fourth time waveform is the time waveform of a current value (command value) for the low-side drive current Ig_LS. The fifth time waveform is the time waveform of a current value (command value) for the low-side drive current Ig_LS according to the modification of Embodiment 1.

At time point t4, when the control signal IN_LS changes from “Hi” to “Lo”, the low-side drive circuit 20A starts supply of the drive current Ig_LS in accordance with the predetermined current value Ig_off6. In order to shorten a turn-off delay time (t4 to t5) of the switching element 11A, it is preferable that the absolute value of the current Ig_off6 be as large as possible within a range in which an operation of the switching element 11A is stable. For example, the current value Ig_off6 may be a value corresponding to a maximum current value that the second variable current source 26 can output in the negative direction (reverse direction from the switching element 11A to the drive circuit 20A).

At time point t5, when the drain-source voltage Vds_LS starts to increase, the low-side drive circuit 20A switches the current value (command value) for the drive current Ig_LS to the current value Ig_off7 having an absolute value smaller than that of the current value Ig_off6 so as to control the voltage slew rate in the third period (t5 to t6).

At time point ty, the low-side drive circuit 20A switches the current value for the drive current Ig_LS to the predetermined current value Ig_off10 having an absolute value further smaller than that of the current value Ig_off7 so as to suppress the surge of the drain-source voltage Vds_LS. In order to suppress the surge of the drain-source voltage Vds_LS, it is preferable that the absolute value of the current Ig_off10 be as small as possible within a range in which an operation of the switching element 11A is stable. However, when the absolute value of the current value Ig_off10 is excessively small, the third period (t5 to t6) is long. The absolute value of the current value Ig_off10 is experimentally determined in advance to be a predetermined value having an absolute value smaller than that of the current value Ig_off7 in consideration of a trade-off therebetween. For example, the current value Ig_off10 may be zero or a negative value close to zero.

At time point t6, when the drain current Id_LS starts to substantially decrease, the low-side drive circuit 20A switches the current value for the drive current Ig_LS to the current value Ig_off8 having an absolute value smaller than that of the current value Ig_off6 so as to control the current slew rate in the fourth period (t6 to t7).

At time point t6 or later, the second calculation circuit 42 calculates the slew rate (third voltage slew rate) SRV_off3 of the drain-source voltage Vds, which is defined by Expression (19) described above, based on the voltage Vfc_LS and the transition timings (t5 and t6) detected by the second detection circuit 41.

The second adder 43 calculates the deviation ε3 between the third voltage slew rate SRV_off3 calculated by the second calculation circuit 42 and the predetermined target value RefV_off3. The second storage 44 corrects (overwrites) the current value Ig_off7 stored in itself in accordance with the deviation ε3 calculated by the second adder 43. Specifically, when the absolute value of the third voltage slew

rate SRV_off3 in the n-th turn-off duration is larger than the absolute value of the target value RefV_off3, the second storage 44 corrects the absolute value of the current value Ig_off7 stored in itself to a smaller value in accordance with the deviation ε3. On the other hand, when the absolute value of the third voltage slew rate SRV_off3 in the n-th turn-off duration is smaller than the absolute value of the target value RefV_off3, the second storage 44 corrects the absolute value of the current value Ig_off7 stored in itself to a larger value in accordance with the deviation ε3. Accordingly, the current value Ig_off7 for the drive current in the third period is controlled so that the third voltage slew rate SRV_off3 matches the target value RefV_off3.

At time point t7, when the drain current Id_LS becomes zero, the low-side drive circuit 20A switches the magnitude of the drive current Ig_LS to the predetermined current value Ig_off9 so as to prevent an unexpected malfunction during an off-period of the switching element 11A. In order to prevent the switching element 11A from being turned on due to a malfunction, it is preferable that the absolute value of the current Ig_off9 be as large as possible within a range in which an operation of the switching element 11A is stable. For example, the current value Ig_off9 may be a value in accordance with a maximum current value that the second variable current source 26 can output in the negative direction (reverse direction from the switching element 11A to the drive circuit 20A).

At time point t7 or later, the second calculation circuit 42 calculates the slew rate (fourth current slew rate) SRI_off4 of the drain current Id_LS, which is defined by Expression (20) described above, based on the voltage Vfc_LS and the transition timings (time points t6 and t7) detected by the second detection circuit 41.

The second adder 43 calculates the deviation ε4 between the fourth current slew rate SRI_off4 calculated by the second calculation circuit 42 and the predetermined target value RefI_off4. The second storage 44 corrects (overwrites) the current value Ig_off8 stored in itself in accordance with the deviation ε4 calculated by the second adder 43.

Specifically, when the absolute value of the fourth current slew rate SRI_off4 in the n-th turn-off duration is larger than the absolute value of the target value RefI_off4, the second storage 44 corrects the absolute value of the current value Ig_off8 stored in itself to a smaller value in accordance with the deviation ε4. On the other hand, when the absolute value of the fourth current slew rate SRI_off4 in the n-th turn-off duration is smaller than the absolute value of the target value RefI_off4, the second storage 44 corrects the absolute value of the current value Ig_off8 stored in itself to a larger value in accordance with the deviation 84. Accordingly, the current value Ig_off8 for the drive current in the fourth period is controlled so that the fourth current slew rate SRI_off4 matches the target value RefI_off4.

The drive current Ig_LS of the switching element 11A during turn-off is controlled as described above. Note that, as a modification, when suppression of the surge of the drain-source voltage Vds_LS is not required, the second detection circuit 41 may omit detection of the preliminary timing (ty). In this case, the time waveform of the current value (command value) for the drive current Ig_LS is as illustrated in the fifth graph in FIG. 8.

As described above, at each transition timing, the drive circuit 20 according to Embodiment 1 switches a current value (command value) for the drive current Ig to be supplied to the switching element 11, thereby supplying the drive current Ig having a magnitude that can differ in respective periods to the switching element 11. Accordingly, the slew rate of the output voltage Vds or the output current Id of the switching element 11 in each period can be separately controlled.

Specifically, the drive circuit 20 separately controls the current values Ig_on2 and Ig_on3 for the drive current Ig in each of the first period (time point t1 to time point t2) and the second period (time point t2 to time point t3) during turn-on so as to separately control the slew rate of the switching element 11 in the period. The drive circuit 20 also separately controls current values Ig_off7 and Ig_off8 for the drive current Ig in each of the third period (time point t5 to time point t6) and the fourth period (time point t6 to time point t7) during turn-off so as to separately control the slew rate of the switching element 11 in the period. Accordingly, the slew rate of the output voltage Vds or the output current Id of the switching element 11 in each period can be separately controlled. In other words, the slew rate of the output voltage Vds or the output current Id of the switching element 11 can be flexibly and accurately controlled.

In addition, the drive circuit 20 detects the preliminary timing (tx) right before the output current Id reaches a maximum value during turn-on of the switching element 11, and switches the current value for the drive current Ig to the current value Ig_on5 having an absolute value smaller than that of the current value Ig_on2 at the preliminary timing. Accordingly, the surge of the output current Id can be suppressed.

Similarly, the drive circuit 20 detects the preliminary timing (ty) right before the output voltage Vds reaches a maximum value during turn-off of the switching element 11, and switches the current value for the drive current Ig to the current value Ig_off10 having an absolute value smaller than that of the current value Ig_off7 at the preliminary timing. Accordingly, the surge of the output voltage Vds can be suppressed.

In addition, upon completion of turn-on of the switching element 11 (t3), the drive circuit 20 switches the current value for the drive current Ig to the current value Ig_on4 corresponding to a maximum current value in the positive direction (forward direction from the drive circuit to the switching element), for example. Accordingly, an unexpected malfunction of the switching element 11 during an on-period is prevented.

Similarly, upon completion of turn-off of the switching element 11 (t7), the drive circuit 20 switches the current value for the drive current Ig to the current value Ig_off9 corresponding to a maximum current value in the negative direction (reverse direction from the switching element to the drive circuit), for example. Accordingly, an unexpected malfunction of the switching element 11 during an off-period is prevented.

### Embodiment 2

In Embodiment 2, during turn-on, only the slew rate of the output voltage Vds or the output current Id in the first period (time point t1 to time point t2) is controlled, whereas control of the slew rate in the second period (time point t2 to time point t3) is omitted. Similarly, during turn-off, only the slew rate of the output voltage Vds in the third period (time point t5 to time point t6) is controlled, whereas control of the slew rate in the fourth period (time point t6 to time point t7) is omitted.

### Configuration of Drive Circuit

The configuration of the drive circuit according to Embodiment 2 is the same as in Embodiment 1. Accordingly, the same reference signs as in Embodiment 1 are used in the following description.

### Operation of Drive Circuit During Turn-on

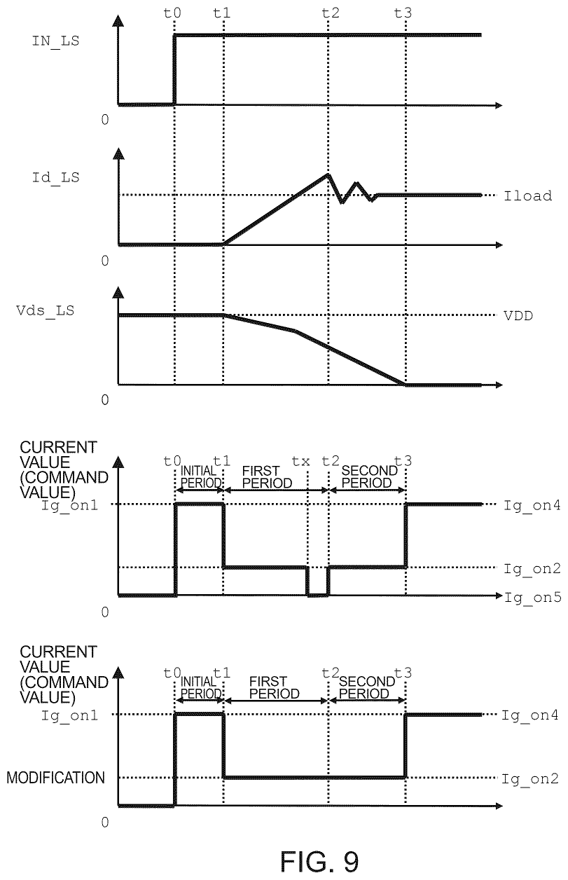

FIG. 9 is a diagram for description of an operation of the low-side drive circuit 20A according to Embodiment 2 during turn-on. Note that the high-side drive circuit 20B performs the same operation, and thus the following description will be made only on the operation of the low-side drive circuit 20A. The uppermost time waveform is the time waveform of the low-side control signal IN_LS. The second time waveform is the time waveform of the drain current Id_LS of the switching element 11A. The third time waveform is the time waveform of the drain-source voltage Vds_LS of the switching element 11A. The fourth time waveform is the time waveform of a current value (command value) for the low-side drive current Ig_LS. The fifth time waveform is the time waveform of a current value (command value) for the low-side drive current Ig_LS according to a modification of Embodiment 2.

At time point t0, when the control signal IN_LS changes from “Lo” to “Hi”, the low-side drive circuit 20A starts supply of the drive current Ig_LS in accordance with the predetermined current value Ig_on1. For example, the current value Ig_on1 may be a value corresponding to a maximum current value that the first variable current source 24 can output in the positive direction (forward from the drive circuit 20A to the switching element 11A).

At time point t1, when the drain current Id_LS starts to flow and the drain-source voltage Vds_LS starts to decrease, the low-side drive circuit 20A switches the current value for the drive current Ig_LS to the current value Ig_on2 that is smaller than the current value Ig_on1 so as to control the voltage slew rate or the current slew rate in the first period (t1 to t2).

At time point tx, the low-side drive circuit 20A switches the current value for the drive current Ig_LS to the predetermined current value Ig_on5 that is further smaller than the current value Ig_on2 so as to suppress the surge of the drain current Id_LS. For example, the current value Ig_on5 may be zero or a positive value close to zero.

At time point t2, when the drain current Id_LS reaches a maximum value, the low-side drive circuit 20A switches the current value for the drive current Ig_LS back to the current value Ig_on2.

At time point t2 or later, the first calculation circuit 32 calculates the slew rate (first voltage slew rate) SRV_on1 of the drain-source voltage Vds, which is defined by Expression (13) described above, based on the voltage Vfc_LS and the transition timings (t1 and t2) detected by the first detection circuit 31.

The first adder 33 calculates the deviation ε1 between the first voltage slew rate SRV_on1 calculated by the first calculation circuit 32 and the predetermined target value RefV_on1. The first storage 34 corrects (overwrites) the current value Ig_on2 stored in itself in accordance with the deviation ε1 calculated by the first adder 33. Accordingly, the current value Ig_on2 for the drive current in the first period is controlled so that the first voltage slew rate SRV_on1 matches the target value RefV_on1.

Alternatively, the first calculation circuit 32 may calculate the slew rate (first current slew rate) SRI_on1 of the drain current Id_LS, which is defined by Expression (14) described above, based on the voltage Vfb_LS and the transition timings (time points t1 and t2) detected by the first detection circuit 31.

The first adder 33 calculates the deviation ε1 between the first current slew rate SRI_on1 calculated by the first calculation circuit 32 and the predetermined target value RefI_on1. The first storage 34 corrects (overwrites) the current value Ig_on2 stored in itself in accordance with the deviation ε1 calculated by the first adder 33. Accordingly, the current value Ig_on2 for the drive current in the first period (time point t1 to time point t2) is controlled so that the first current slew rate SRI_on1 matches the target value RefI_on1.

At time point t3, when the drain-source voltage Vds_LS becomes zero, the low-side drive circuit 20A switches the current value for the drive current Ig_LS to the predetermined current value Ig_on4 so as to prevent an unexpected malfunction of the switching element 11A during an on-period. For example, the current value Ig_on4 may be a value corresponding to a maximum current value that the first variable current source 24 can output in the positive direction (forward direction from the drive circuit 20A to the switching element 11A).

The drive current Ig_LS of the switching element 11A during turn-on is controlled as described above. Note that, as a modification, when suppression of the surge of the drain current Id_LS is not required, the first detection circuit 31 may omit detection of the preliminary timing (tx). In this case, the time waveform of the current value for the drive current Ig_LS is as illustrated in the fifth graph in FIG. 9.

### Operation of Drive Circuit During Turn-Off

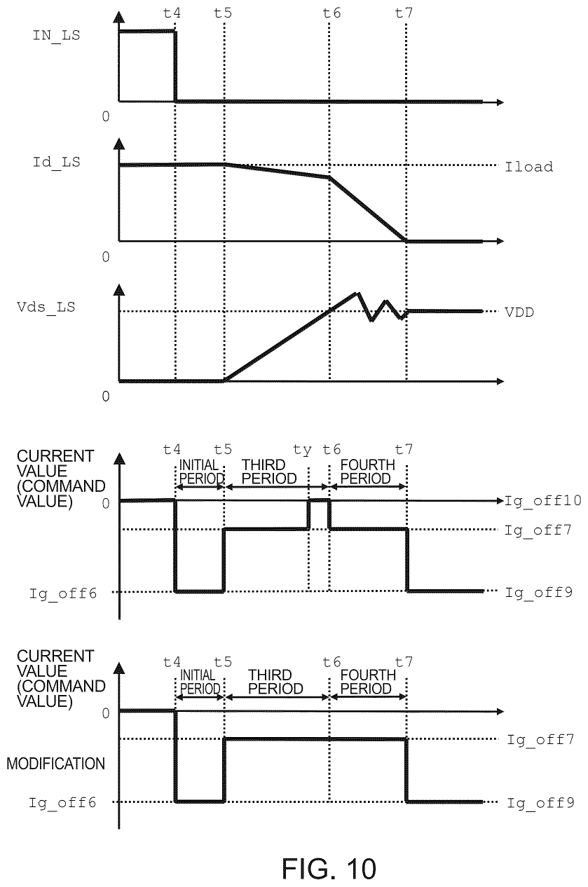

FIG. 10 is a diagram for description of an operation of the low-side drive circuit 20A according to Embodiment 2 during turn-off. Note that the high-side drive circuit 20B performs the same operation, and thus the following description will be made only on the operation of the low-side drive circuit 20A. The uppermost time waveform is the time waveform of the low-side control signal IN_LS. The second time waveform is the time waveform of the drain current Id_LS of the switching element 11A. The third time waveform is the time waveform of the drain-source voltage Vds_LS of the switching element 11A. The fourth time waveform is the time waveform of a current value (command value) for the low-side drive current Ig_LS. The fifth time waveform is the time waveform of a current value (command value) for the low-side drive current Ig_LS according to a modification of Embodiment 2.

At time point t4, when the control signal IN_LS changes from “Hi” to “Lo”, the low-side drive circuit 20A starts supply of the drive current Ig_LS having the predetermined current value Ig_off6. For example, the current value Ig_off6 may be a value corresponding to a maximum current value that the second variable current source 26 can output in the negative direction (reverse direction from the switching element 11A to the drive circuit 20A).

At time point t5, when the drain-source voltage Vds_LS starts to increase, the low-side drive circuit 20A switches the current value for the drive current Ig_LS to the current value Ig_off7 having an absolute value smaller than that of the current value Ig_off6 so as to control the voltage slew rate in the third period (t5 to t6).

At time point ty, the low-side drive circuit 20A switches the current value for the drive current Ig_LS to the predetermined current value Ig_off10 having an absolute value further smaller than the current value Ig_off7 so as to suppress the surge of the drain-source voltage Vds_LS. For example, the current value Ig_off10 may be zero or a negative value close to zero.

At time point t6, when the drain current Id_LS starts to substantially decrease, the low-side drive circuit 20A switches the current value for the drive current Ig_LS back to the current value Ig_off7.

At time point t6 or later, the second calculation circuit 42 calculates the slew rate (third voltage slew rate) SRV_off3 of the drain-source voltage Vds, which is defined by Expression (19) described above, based on the voltage Vfc_LS and the transition timings (t5 and t6) detected by the second detection circuit 41.

The second adder 43 calculates the deviation ε3 between the third voltage slew rate SRV_off3 calculated by the second calculation circuit 42 and the predetermined target value RefV_off3. The second storage 44 corrects (overwrites) the current value Ig_off7 stored in itself in accordance with the deviation ε3 calculated by the second adder 43. Accordingly, the current value Ig_off7 for the drive current in the third period is controlled so that the third voltage slew rate SRV_off3 matches the target value RefV_off3.

At time point t7, when the drain current Id_LS becomes zero, the low-side drive circuit 20A switches the current value for the drive current Ig_LS to the predetermined current value Ig_off9 so as to prevent an unexpected malfunction of the switching element 11A during an off-period. For example, the current value Ig_off9 may be a value corresponding to a maximum current value that the second variable current source 26 can output in the negative direction (reverse direction from the switching element 11A to the drive circuit 20A).

The drive current Ig_LS of the switching element 11A during turn-off is controlled as described above. Note that, as a modification, when suppression of the surge of the drain-source voltage Vds_LS is not required, the second detection circuit 41 may omit detection of the preliminary timing (ty). In this case, the time waveform of the current value (command value) for the drive current Ig_LS is as illustrated in the fifth graph in FIG. 10.

### Embodiment 3

In Embodiment 3, during turn-on, only the slew rate of the output voltage Vds in the second period (time point t2 to time point t3) is controlled, whereas control of the slew rate in the first period (time point t1 to time point t2) is omitted. Similarly, during turn-off, only the slew rate of the output current Id in the fourth period (time point t6 to time point t7) is controlled, whereas control of the slew rate in the third period (time point t5 to time point t6) is omitted.

### Configuration of Drive Circuit

The configuration of the drive circuit according to Embodiment 3 is the same as in Embodiment 1. Accordingly, the same reference signs as in Embodiment 1 are used in the following description.

### Operation of Drive Circuit During Turn-on

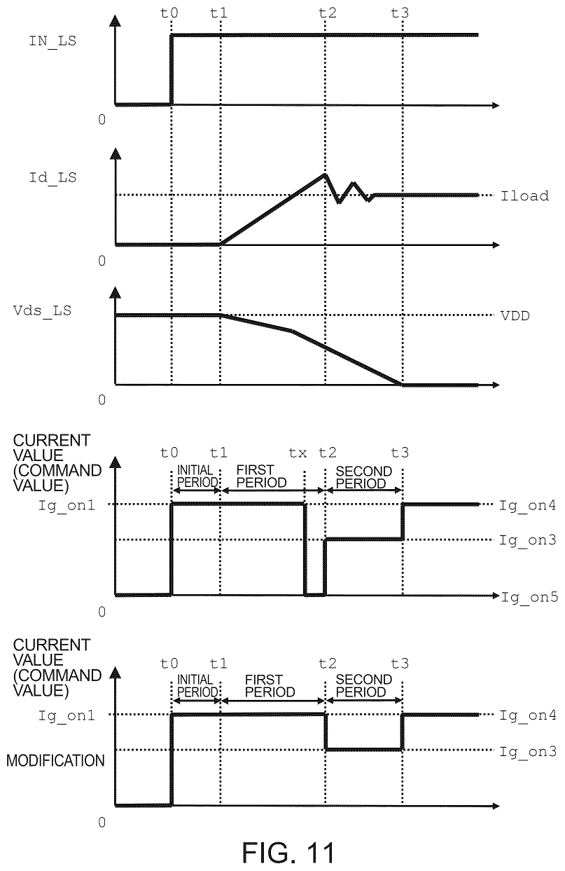

FIG. 11 is a diagram for description of an operation of the low-side drive circuit 20A according to Embodiment 1 during turn-on. Note that the high-side drive circuit 20B performs the same operation, and thus the following description will be made only on the operation of the low-side drive circuit 20A. The uppermost time waveform is the time waveform of the low-side control signal IN_LS. The second time waveform is the time waveform of the drain current Id_LS of the switching element 11A. The third time waveform is the time waveform of the drain-source voltage Vds_LS of the switching element 11A. The fourth time waveform is the time waveform of a current value (command value) for the low-side drive current Ig_LS. The fifth time waveform is the time waveform of a current value (command value) for the low-side drive current Ig_LS according to a modification of Embodiment 3.

At time point t0, when the control signal IN_LS changes from “Lo” to “Hi”, the low-side drive circuit 20A starts supply of the drive current Ig_LS in accordance with the predetermined current value Ig_on1. For example, the current value Ig_on1 may be a value corresponding to a maximum current value that the first variable current source 24 can output in the positive direction (forward direction from the drive circuit 20A to the switching element 11A).

At time point tx, the low-side drive circuit 20A switches the current value for the drive current Ig_LS to the predetermined current value Ig_on5 that is smaller than the current value Ig_on1 so as to suppress the surge of the drain current Id_LS. For example, the current value Ig_on5 may be zero or a positive value close to zero.

At time point t2, when the drain current Id_LS reaches a maximum value, the low-side drive circuit 20A switches the current value for the drive current Ig_LS to the current value Ig_on3 that is smaller than the current value Ig_on1 so as to control the voltage slew rate in the second period (t2 to t3).

At time point t3, when the drain-source voltage Vds_LS becomes zero, the low-side drive circuit 20A switches the current value for the drive current Ig_LS to the predetermined current value Ig_on4 so as to prevent an unexpected malfunction of the switching element 11A during an on-period. For example, the current value Ig_on4 may be a value corresponding to a maximum current value that the first variable current source 24 can output in the positive direction (forward direction from the drive circuit 20A to the switching element 11A).

At time point t3 or later, the first calculation circuit 32 calculates the slew rate (second voltage slew rate) SRV_on2 of the drain-source voltage Vds, which is defined by Expression (15) described above, based on the voltage Vfc_LS and the transition timings (time points t2 and t3) detected by the first detection circuit 31.

The first adder 33 calculates the deviation ε2 between the second voltage slew rate SRV_on2 calculated by the first calculation circuit 32 and the predetermined target value RefV_on2. The first storage 34 corrects (overwrites) the current value Ig_on3 stored in itself in accordance with the deviation ε2 calculated by the first adder 33. Accordingly, the current value Ig_on3 for the drive current in the second period is controlled so that the second voltage slew rate SRV_on2 matches the target value RefV_on2.

The drive current Ig_LS of the switching element 11A during turn-on is controlled as described above. Note that, as a modification, when suppression of the surge of the drain current Id_LS is not required, the first detection circuit 31 may omit detection of the preliminary timing (tx). In this case, the time waveform of the current value (command value) for the drive current Ig_LS is as illustrated in the fifth graph in FIG. 11.

### Operation of Drive Circuit During Turn-Off

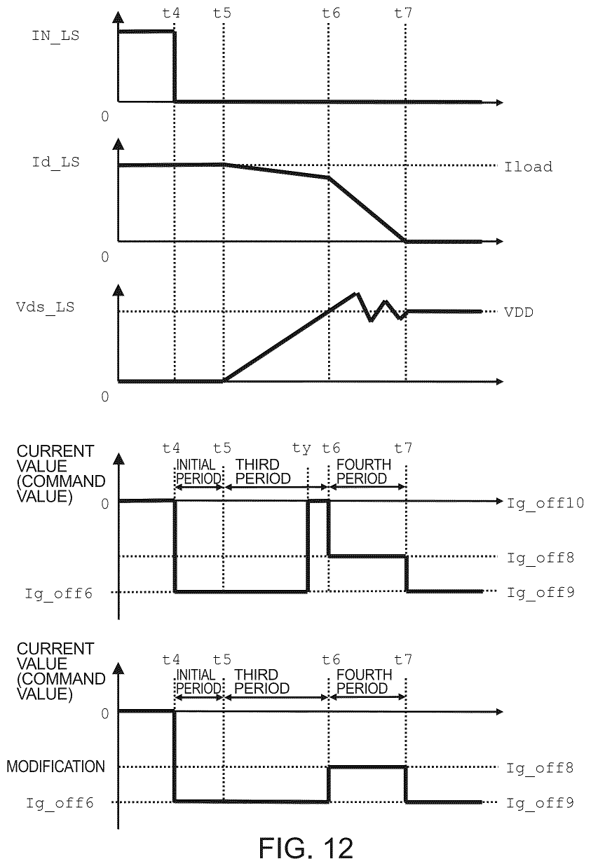

FIG. 12 is a diagram for description of an operation of the low-side drive circuit 20A according to Embodiment 3 during turn-off. Note that the high-side drive circuit 20B performs the same operation, and thus the following description will be made only on the operation of the low-side drive circuit 20A. The uppermost time waveform is the time waveform of the low-side control signal IN_LS. The second time waveform is the time waveform of the drain current Id_LS of the switching element 11A. The third time waveform is the time waveform of the drain-source voltage Vds_LS of the switching element 11A. The fourth time waveform is the time waveform of a current value (command value) for the low-side drive current Ig_LS. The fifth time waveform is the time waveform of a current value (command value) for the low-side drive current Ig_LS according to a modification of Embodiment 3.

At time point t4, when the control signal IN_LS changes from “Hi” to “Lo”, the low-side drive circuit 20A starts supply of the drive current Ig_LS in accordance with the predetermined current value Ig_off6. For example, the current value Ig_off6 may be a value corresponding to a maximum current value that the second variable current source 26 can output in the negative direction (reverse direction from the switching element 11A to the drive circuit 20A).

At time point ty, the low-side drive circuit 20A switches the current value for the drive current Ig_LS to the predetermined current value Ig_off10 having an absolute value smaller than that of the current value Ig_off6 so as to suppress the surge of the drain-source voltage Vds_LS. For example, the current value Ig_off10 may be zero or a negative value close to zero.

At time point t6, when the drain current Id_LS starts to substantially decrease, the low-side drive circuit 20A switches the current value for the drive current Ig_LS to the current value Ig_off8 having an absolute value smaller than that of the current value Ig_off6 so as to control the current slew rate in the fourth period (t6 to t7).

At time point t7, when the drain current Id_LS becomes zero, the low-side drive circuit 20A switches the current value for the drive current Ig_LS to the predetermined current value Ig_off9 so as to prevent an unexpected malfunction of the switching element 11A. For example, the current value Ig_off9 may be a value corresponding to a maximum current value that the second variable current source 26 can output in the negative direction (reverse direction from the switching element 11A to the drive circuit 20A).

At time point t7 or later, the second calculation circuit 42 calculates the slew rate (fourth current slew rate) SRI_off4 of the drain current Id_LS, which is defined by Expression (20) described above, based on the voltage Vfc_LS and the transition timings (time points t6 and t7) detected by the second detection circuit 41.

The second adder 43 calculates the deviation ε4 between the fourth current slew rate SRI_off4 calculated by the second calculation circuit 42 and the predetermined target value RefI_off4. The second storage 44 corrects (overwrites) the current value Ig_off8 stored in itself in accordance with the deviation ε4 calculated by the second adder 43. Accordingly, the current value Ig_off8 for the drive current in the fourth period is controlled so that the fourth current slew rate SRI_off4 matches the target value RefI_off4.

The drive current Ig_LS of the switching element 11A during turn-off is controlled as described above. Note that, as a modification, when suppression of the surge of the drain-source voltage Vds_LS is not required, the second detection circuit 41 may omit detection of the preliminary timing (ty). In this case, the time waveform of the current value (command value) for the drive current Ig_LS is as illustrated in the fifth graph in FIG. 12.

### Embodiment 4

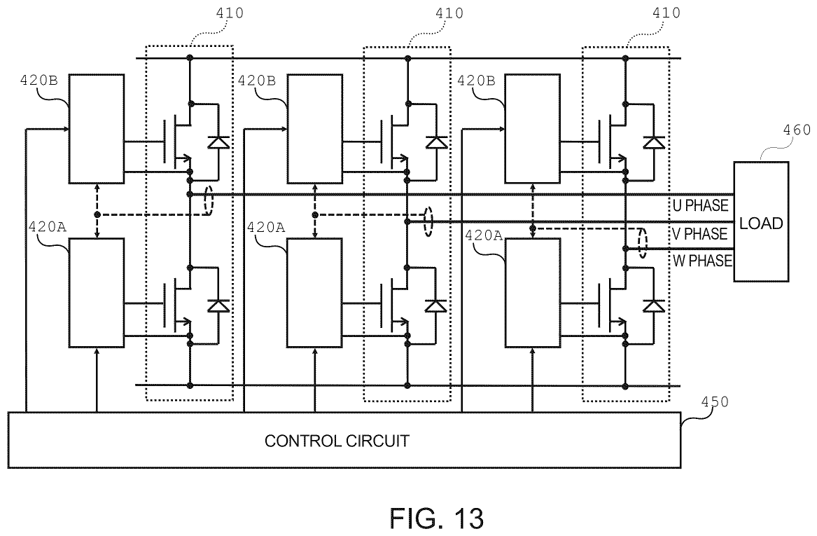

FIG. 13 is a diagram illustrating the configuration of a three-phase inverter according to Embodiment 4. The three-phase inverter includes three half-bridge circuits 410, three low-side drive circuits 420A, three high-side drive circuits 420B, and a control circuit 450. A load 460 is connected to an output of the three-phase inverter. Each half-bridge circuit 410 has the same configuration as the half-bridge circuit in Embodiment 1 to 3. Each low-side drive circuit 420A has the same configuration as the low-side drive circuit in Embodiment 1 to 3. Each high-side drive circuit 420B has the same configuration as the high-side drive circuit in Embodiment 1 to 3.

The control circuit 450 supplies a low-side control signal to each low-side drive circuit 420A, and supplies a high-side control signal to each high-side drive circuit 420B. The load 460 is an optional electronic apparatus or electric apparatus that is driven by three-phase alternating-current power. For example, in a case where the load 460 is a three-phase alternating-current motor, the control circuit 450 supplies the PWM-modulated low-side control signal to each low-side drive circuit 420A, and supplies the PWM-modulated high-side control signal to each high-side drive circuit 420B.

As another application example, an inverter including a low-side drive circuit, a high-side drive circuit, a half-bridge circuit, and a control circuit may be used as a PV inverter for photovoltaic power generation. In this case, an output of the PV inverter is connected to a power grid.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

The embodiments as described before may be configured as below.

### CLAUSES

### (Clauses) Clause 1. (Electronic Circuitry)

An electronic circuitry comprising: a detection circuit configured to detect a physical quantity corresponding to a temporal change of an output current or an output voltage of a switching element whose drive is controlled in accordance with a control signal instructing turn-on or turn-off; a controller configured to switch a current value commanding a magnitude of a drive current to be supplied to the switching element at a transition timing corresponding to the detected physical quantity; a current supply circuit configured to supply the drive current to the switching element based on the current value before switching and the current value after switching; and a calculation circuit configured to calculate a slew rate of the output voltage or the output current of the switching element in a period before the switching or a period after the switching, wherein the controller is configured to determine the current value before switching or the current value after switching to be used during next or subsequent turn-on or turn-off of the switching element in accordance with the calculated slew rate.

### Clause 2. (Embodiment 1) (Ig_on2+Ig_on3)

The electronic circuitry according to clause 1, wherein the control signal is a turn-on signal instructing turn-on of the switching element, the current supply circuit supplies the drive current based on a first current value (Ig_on1) at start of turn-on (t0) of the switching element, the detection circuit detects, based on the physical quantity, a first transition timing (t1) at which the output current starts to flow, a second transition timing (t2) at which the output current reaches a maximum value or the output voltage falls below a predetermined voltage, and a third transition timing (t3) at which the output voltage becomes a minimum value, the controller is configured to switch the current value to a second current value (Ig_on2) smaller than the first current value (Ig_on1) at the first transition timing (t1), and switches the current value to a third current value (Ig_on3) different from the second current value (Ig_on2) and smaller than the first current value (Ig_on1) at the second transition timing (t2), the calculation circuit calculates a first slew rate (SRV_on1, SRI_on1) in a first period (t1 to t2) from the first transition timing to the second transition timing and a second slew rate (SRV_on2) in a second period (t2 to t3) from the second transition timing to the third transition timing, and the controller is configured to determine the second current value (Ig_on2) to be used during next or subsequent turn-on of the switching element in accordance with the first slew rate, and determine the third current value (Ig_on3) to be used during next or subsequent turn-on of the switching element in accordance with the second slew rate.

### Clause 3. (Embodiment 1) (Ig_on4)

The electronic circuitry according to clause 2, wherein the controller is configured to switch the current value to a fourth current value at the third transition timing (t3), and the controller is configured to command, as the fourth current value, a maximum current value in a positive direction that the current supply circuit can supply or a value larger than the third current value.

### Clause 4. (Embodiment 2) (Ig_on2)

The electronic circuitry according to clause 1, wherein the control signal is a turn-on signal instructing turn-on of the switching element, the current supply circuit supplies the drive current based on a first current value (Ig_on1) at start of turn-on of the switching element, the detection circuit detects, based on the physical quantity, a first transition timing (t1) at which the output current starts to flow, and a second transition timing (t2) at which the output current reaches a maximum value or the output voltage falls below a predetermined voltage, the controller is configured to switch the current value to a second current value (Ig_on2) smaller than the first current value (Ig_on1) at the first transition timing (t1), the calculation circuit is configured to calculate a first slew rate (SRV_on1, SRI_on1) in a first period (t1 to t2) from the first transition timing to the second transition timing, and the controller is configured to determine the second current value (Ig_on2) to be used during next or subsequent turn-on of the switching element in accordance with the first slew rate.

### Clause 5. (Embodiment 2) (Ig_on4)

The electronic circuitry according to clause 4, wherein the detection circuit further detects, based on the physical quantity, a third transition timing (t3) at which the output voltage becomes a minimum value, the controller is configured to switch the current value to a fourth current value at the third transition timing (t3), and the controller is configured to command, as the fourth current value, a maximum current value in a positive direction that the current supply circuit can supply or a value larger than the second current value.

### Clause 6. (Embodiment 3) (Ig_on3)

The electronic circuitry according to clause 1, wherein the control signal is a turn-on signal instructing turn-on of the switching element, the current supply circuit supplies the drive current based on a first current value (Ig_on1) at start of turn-on (to) of the switching element, the detection circuit detects, based on the physical quantity, a second transition timing (t2) at which the output current reaches a maximum value or the output voltage falls below a predetermined voltage, and a third transition timing (t3) at which the output voltage becomes a minimum value, the controller is configured to switch the current value to a third current value (Ig_on3) smaller than the first current value (Ig_on1) at the second transition timing (t2), the calculation circuit is configured to calculate a second slew rate (SRV_on2) in a second period (t2 to t3) from the second transition timing to the third transition timing, and the controller is configured to determine the third current value (Ig_on3) to be used during next or subsequent turn-on of the switching element in accordance with the second slew rate.

### Clause 7. (Embodiment 3) (Ig_on4)

The electronic circuitry according to clause 6, wherein the controller is configured to switch the current value to a fourth current value at the third transition timing (t3), and the controller is configured to command, as the fourth current value, a maximum current value in a positive direction that the current supply circuit can supply or a value larger than the third current value.

### Clause 8. (Ig_on5)

The electronic circuitry according to any one of clauses 2 to 7, wherein the detection circuit further detects, based on the physical quantity, a preliminary timing (tx) after the first transition timing (t1) at which the output current starts to flow and before the second transition timing (t2) at which the output current reaches the maximum value or the output voltage falls below the predetermined voltage, the controller is configured to switch the current value to a fifth current value (Ig_on5) at the preliminary timing (tx), and the controller is configured to command, as the fifth current value, zero or a current close to zero, or a value smaller than the second current value.

### Clause 9. (Embodiment 1) (Ig_off7+Ig_off8)

The electronic circuitry according to clause 1, wherein the control signal is a turn-off signal instructing turn-off of the switching element, the current supply circuit supplies the drive current based on a sixth current value (Ig_off6) at start of turn-off (t4) of the switching element, the detection circuit detects, based on the physical quantity, a fifth transition timing (t5) at which the output voltage starts to increase, a sixth transition timing (t6) at which the output current starts to decrease or the output voltage exceeds a predetermined voltage, and a seventh transition timing (t7) at which the output current becomes a minimum value, the controller is configured to switch the current value to a seventh current value (Ig_off7) larger than the sixth current value at the fifth transition timing (t5), and switch the current value to an eighth current value (Ig_off8) different from the seventh current value and larger than the sixth current value at the sixth transition timing (t6), the calculation circuit is configured to calculate a third slew rate (SRV_off3) in a third period (t5 to t6) from the fifth transition timing to the sixth transition timing and a fourth slew rate (SRI_off4) in a fourth period (t6 to t7) from the sixth transition timing to the seventh transition timing, and the controller is configured to determine the seventh current value to be used during next or subsequent turn-off of the switching element in accordance with the third slew rate, and determine the eighth current value to be used during next or subsequent turn-off of the switching element in accordance with the fourth slew rate.

### Clause 10. (Embodiment 3) (Ig_off7+Ig_off8) (Ig_off9)

The electronic circuitry according to clause 9, wherein the controller is configured to switch the current value to a ninth current value at the seventh transition timing (t7), and the controller is configured to command, as the ninth current value, a maximum current in a negative direction that the current supply circuit can supply or a value smaller than the eighth current value.

### Clause 11. (Embodiment 2) (Ig_off7)

The electronic circuitry according to clause 1, wherein the control signal is a turn-off signal instructing turn-off of the switching element, the current supply circuit supplies the drive current based on a sixth current value (Ig_off6) at start of turn-off (t4) of the switching element, the detection circuit detects, based on the physical quantity, a fifth transition timing (t5) at which the output voltage starts to increase, and a sixth transition timing (t6) at which the output current starts to decrease or the output voltage exceeds a predetermined voltage, the controller is configured to switch the current value to a seventh current value (Ig_off7) larger than the sixth current value at the fifth transition timing, the calculation circuit is configured to calculate a third slew rate (SRV_off3) in a third period (t5 to t6) from the fifth transition timing to the sixth transition timing, and the controller is configured to determine the seventh current value to be used during next or subsequent turn-off of the switching element in accordance with the third slew rate.

### Clause 12. (Embodiment 3) (Ig_off7) (Ig_off9)

The electronic circuitry according to clause 11, wherein the detection circuit further detects, based on the physical quantity, a seventh transition timing (t7) at which the output current becomes a minimum value, the controller is configured to switch the current value to a ninth current value at the seventh transition timing (t7), and the controller is configured to command, as the ninth current value, a maximum current in a negative direction that the current supply circuit can supply or a value smaller than the seventh current value.

### Clause 13. (Embodiment 3) (Ig_off8)

The electronic circuitry according to clause 11, wherein the control signal is a turn-off signal instructing turn-off of the switching element, the current supply circuit supplies the drive current based on a sixth current value (Ig_off6) at start of turn-off (t4) of the switching element, the detection circuit detects, based on the physical quantity, a sixth transition timing (t6) at which the output current starts to decrease or the output voltage exceeds a predetermined voltage, and a seventh transition timing (t7) at which the output current becomes a minimum value, the controller is configured to switch the current value to an eighth current value (Ig_off8) larger than the sixth current value (Ig_on1) at the sixth transition timing, the calculation circuit is configured to calculate a fourth slew rate (SRI_off4) in a fourth period (t6 to t7) from the sixth transition timing to the seventh transition timing, and the controller is configured to determines the eighth current value to be used during next or subsequent turn-off of the switching element in accordance with the fourth slew rate.

### Clause 14. (Embodiment 3) (Ig_off8) (Ig_off9)

The electronic circuitry according to clause 13, wherein the controller is configured to switch the current value to a ninth current value at the seventh transition timing (t7), and the controller is configured to command, as the ninth current value, a maximum current value in a negative direction that the current supply circuit can supply or a value smaller than the eighth current value.

### Clause 15. (Ig_off10)

The electronic circuitry according to any one of clauses 9 to 14, wherein the detection circuit further detects, based on the physical quantity, a preliminary timing (ty) after the fifth transition timing and before the sixth transition timing, the controller is configured to switch the current value to a tenth current value (Ig_off10) at the preliminary timing, and the controller is configured to command, as the tenth current value, zero or a current close to zero, or a value larger than the seventh current value.

### Clause 16. (Half-Bridge Inverter)

A power converter comprising: a half-bridge circuit including two switching elements; and two drive circuits configured to drive the two switching elements, respectively, in accordance with control signals instructing turn-on or turn-off, wherein each of the two drive circuits includes: a detection circuit configured to detect a physical quantity corresponding to a temporal change of an output current or an output voltage of the switching element controlled by the drive circuit; a controller configured to switch a current value commanding a magnitude of a drive current to be supplied to the switching element at a transition timing corresponding to the detected physical quantity; a current supply circuit configured to supply the drive current to the switching element based on the current value before switching and the current value after switching; and a calculation circuit configured to calculate a slew rate of the output voltage or the output current of the switching element in a period before the switching or a period after the switching, wherein the controller is configured to determine the current value before switching or the current value after switching to be used during next or subsequent turn-on or turn-off of the switching element in accordance with the calculated slew rate.

### Clause 17. (Three-Phase Inverter)

A power converter apparatus comprising three power converters according to clause 16.

### Clause 18. (Driving Method

A driving method comprising: detecting a physical quantity corresponding to a temporal change of an output current or an output voltage of a switching element whose drive is controlled in accordance with a control signal instructing turn-on or turn-off; switching a current value commanding a magnitude of a drive current to be supplied to the switching element at a transition timing corresponding to the detected physical quantity; supplying the drive current to the switching element based on the current value before switching and the current value after switching; calculating a slew rate of the output voltage or the output current of the switching element in a period before the switching or a period after the switching; and determining the current value before switching or the current value after switching to be used during next or subsequent turn-on or turn-off of the switching element in accordance with the calculated slew rate.

1. An electronic circuitry comprising:
a detection circuit configured to detect a physical quantity corresponding to a temporal change of an output current or an output voltage of a switching element whose drive is controlled in accordance with a control signal instructing turn-on or turn-off;
a controller configured to switch a current value commanding a magnitude of a drive current to be supplied to the switching element at a transition timing corresponding to the detected physical quantity;
a current supply circuit configured to supply the drive current to the switching element based on the current value before switching and the current value after switching; and
a calculation circuit configured to calculate a slew rate of the output voltage or the output current of the switching element in a period before the switching or a period after the switching,
wherein the controller is configured to determine the current value before switching or the current value after switching to be used during next or subsequent turn-on or turn-off of the switching element in accordance with the calculated slew rate.

2. The electronic circuitry according to claim 1, wherein
the control signal is a turn-on signal instructing turn-on of the switching element,
the current supply circuit supplies the drive current based on a first current value at start of turn-on of the switching element,
the detection circuit detects, based on the physical quantity, a first transition timing at which the output current starts to flow, a second transition timing at which the output current reaches a maximum value or the output voltage falls below a predetermined voltage, and a third transition timing at which the output voltage becomes a minimum value,
the controller is configured to switch the current value to a second current value smaller than the first current value at the first transition timing, and switches the current value to a third current value different from the second current value and smaller than the first current value at the second transition timing,
the calculation circuit calculates a first slew rate in a first period from the first transition timing to the second transition timing and a second slew rate in a second period from the second transition timing to the third transition timing, and
the controller is configured to determine the second current value to be used during next or subsequent turn-on of the switching element in accordance with the first slew rate, and determine the third current value to be used during next or subsequent turn-on of the switching element in accordance with the second slew rate.

3. The electronic circuitry according to claim 2, wherein
the controller is configured to switch the current value to a fourth current value at the third transition timing, and
the controller is configured to command, as the fourth current value, a maximum current value in a positive direction that the current supply circuit can supply or a value larger than the third current value.

4. The electronic circuitry according to claim 1, wherein
the control signal is a turn-on signal instructing turn-on of the switching element,
the current supply circuit supplies the drive current based on a first current value at start of turn-on of the switching element,
the detection circuit detects, based on the physical quantity, a first transition timing at which the output current starts to flow, and a second transition timing at which the output current reaches a maximum value or the output voltage falls below a predetermined voltage,
the controller is configured to switch the current value to a second current value smaller than the first current value at the first transition timing,
the calculation circuit is configured to calculate a first slew rate in a first period from the first transition timing to the second transition timing, and
the controller is configured to determine the second current value to be used during next or subsequent turn-on of the switching element in accordance with the first slew rate.

5. The electronic circuitry according to claim 4, wherein
the detection circuit further detects, based on the physical quantity, a third transition timing at which the output voltage becomes a minimum value,
the controller is configured to switch the current value to a fourth current value at the third transition timing, and
the controller is configured to command, as the fourth current value, a maximum current value in a positive direction that the current supply circuit can supply or a value larger than the second current value.

6. The electronic circuitry according to claim 1, wherein
the control signal is a turn-on signal instructing turn-on of the switching element,
the current supply circuit supplies the drive current based on a first current value at start of turn-on of the switching element,
the detection circuit detects, based on the physical quantity, a second transition timing at which the output current reaches a maximum value or the output voltage falls below a predetermined voltage, and a third transition timing at which the output voltage becomes a minimum value,
the controller is configured to switch the current value to a third current value smaller than the first current value at the second transition timing,
the calculation circuit is configured to calculate a second slew rate in a second period from the second transition timing to the third transition timing, and
the controller is configured to determine the third current value to be used during next or subsequent turn-on of the switching element in accordance with the second slew rate.

7. The electronic circuitry according to claim 6, wherein
the controller is configured to switch the current value to a fourth current value at the third transition timing, and
the controller is configured to command, as the fourth current value, a maximum current value in a positive direction that the current supply circuit can supply or a value larger than the third current value.

8. The electronic circuitry according to claim 2, wherein
the detection circuit further detects, based on the physical quantity, a preliminary timing after the first transition timing at which the output current starts to flow and before the second transition timing at which the output current reaches the maximum value or the output voltage falls below the predetermined voltage,
the controller is configured to switch the current value to a fifth current value at the preliminary timing, and
the controller is configured to command, as the fifth current value, zero or a current close to zero, or a value smaller than the second current value.

9. The electronic circuitry according to claim 1, wherein
the control signal is a turn-off signal instructing turn-off of the switching element,
the current supply circuit supplies the drive current based on a sixth current value at start of turn-off of the switching element,
the detection circuit detects, based on the physical quantity, a fifth transition timing at which the output voltage starts to increase, a sixth transition timing at which the output current starts to decrease or the output voltage exceeds a predetermined voltage, and a seventh transition timing at which the output current becomes a minimum value,
the controller is configured to switch the current value to a seventh current value larger than the sixth current value at the fifth transition timing, and switch the current value to an eighth current value different from the seventh current value and larger than the sixth current value at the sixth transition timing,
the calculation circuit is configured to calculate a third slew rate in a third period from the fifth transition timing to the sixth transition timing and a fourth slew rate in a fourth period from the sixth transition timing to the seventh transition timing, and
the controller is configured to determine the seventh current value to be used during next or subsequent turn-off of the switching element in accordance with the third slew rate, and determine the eighth current value to be used during next or subsequent turn-off of the switching element in accordance with the fourth slew rate.

10. The electronic circuitry according to claim 9, wherein
the controller is configured to switch the current value to a ninth current value at the seventh transition timing, and
the controller is configured to command, as the ninth current value, a maximum current in a negative direction that the current supply circuit can supply or a value smaller than the eighth current value.

11. The electronic circuitry according to claim 1, wherein
the control signal is a turn-off signal instructing turn-off of the switching element,
the current supply circuit supplies the drive current based on a sixth current value at start of turn-off of the switching element,
the detection circuit detects, based on the physical quantity, a fifth transition timing at which the output voltage starts to increase, and a sixth transition timing at which the output current starts to decrease or the output voltage exceeds a predetermined voltage,
the controller is configured to switch the current value to a seventh current value larger than the sixth current value at the fifth transition timing,
the calculation circuit is configured to calculate a third slew rate in a third period from the fifth transition timing to the sixth transition timing, and
the controller is configured to determine the seventh current value to be used during next or subsequent turn-off of the switching element in accordance with the third slew rate.

12. The electronic circuitry according to claim 11, wherein
the detection circuit further detects, based on the physical quantity, a seventh transition timing at which the output current becomes a minimum value,
the controller is configured to switch the current value to a ninth current value at the seventh transition timing, and
the controller is configured to command, as the ninth current value, a maximum current in a negative direction that the current supply circuit can supply or a value smaller than the seventh current value.

13. The electronic circuitry according to claim 11, wherein
the control signal is a turn-off signal instructing turn-off of the switching element,
the current supply circuit supplies the drive current based on a sixth current value at start of turn-off of the switching element,
the detection circuit detects, based on the physical quantity, a sixth transition timing at which the output current starts to decrease or the output voltage exceeds a predetermined voltage, and a seventh transition timing at which the output current becomes a minimum value,
the controller is configured to switch the current value to an eighth current value larger than the sixth current value at the sixth transition timing,
the calculation circuit is configured to calculate a fourth slew rate in a fourth period from the sixth transition timing to the seventh transition timing, and
the controller is configured to determines the eighth current value to be used during next or subsequent turn-off of the switching element in accordance with the fourth slew rate.

14. The electronic circuitry according to claim 13, wherein
the controller is configured to switch the current value to a ninth current value at the seventh transition timing, and
the controller is configured to command, as the ninth current value, a maximum current value in a negative direction that the current supply circuit can supply or a value smaller than the eighth current value.

15. The electronic circuitry according to claim 9, wherein
the detection circuit further detects, based on the physical quantity, a preliminary timing after the fifth transition timing and before the sixth transition timing,
the controller is configured to switch the current value to a tenth current value at the preliminary timing, and
the controller is configured to command, as the tenth current value, zero or a current close to zero, or a value larger than the seventh current value.

16. A power converter comprising:
a half-bridge circuit including two switching elements; and
two drive circuits configured to drive the two switching elements, respectively, in accordance with control signals instructing turn-on or turn-off,
wherein each of the two drive circuits includes:
a detection circuit configured to detect a physical quantity corresponding to a temporal change of an output current or an output voltage of the switching element controlled by the drive circuit;
a controller configured to switch a current value commanding a magnitude of a drive current to be supplied to the switching element at a transition timing corresponding to the detected physical quantity;
a current supply circuit configured to supply the drive current to the switching element based on the current value before switching and the current value after switching; and
a calculation circuit configured to calculate a slew rate of the output voltage or the output current of the switching element in a period before the switching or a period after the switching,
wherein the controller is configured to determine the current value before switching or the current value after switching to be used during next or subsequent turn-on or turn-off of the switching element in accordance with the calculated slew rate.

17. A power converter apparatus comprising three power converters according to claim 16.

18. A driving method comprising:
detecting a physical quantity corresponding to a temporal change of an output current or an output voltage of a switching element whose drive is controlled in accordance with a control signal instructing turn-on or turn-off;
switching a current value commanding a magnitude of a drive current to be supplied to the switching element at a transition timing corresponding to the detected physical quantity;
supplying the drive current to the switching element based on the current value before switching and the current value after switching;
calculating a slew rate of the output voltage or the output current of the switching element in a period before the switching or a period after the switching; and
determining the current value before switching or the current value after switching to be used during next or subsequent turn-on or turn-off of the switching element in accordance with the calculated slew rate.
